(19) United States
(12) Patent Application Publication
(10) Pub. No.: US 2022/0077312 A1
(43) Pub. Date: Mar. 10, 2022

(54) SEMICONDUCTOR DEVICE AND METHOD OF MANUFACTURING SEMICONDUCTOR DEVICE

(71) Applicant: FUJI ELECTRIC CO., LTD., Kawasaki-shi (JP)

(72) Inventor: Yasuyuki HOSHI, Matsumoto-city (JP)

(73) Assignee: FUJI ELECTRIC CO., LTD., Kawasaki-shi (JP)

(21) Appl. No.: 17/388,878

(22) Filed: Jul. 29, 2021

(30) Foreign Application Priority Data
Sep. 8, 2020 (JP) 2020-150445

(51) Int. Cl. H01L 29/78; H01L 29/66

(52) U.S. Cl. CPC H01L 29/7811; H01L 29/66734; H01L 29/1608; H01L 29/7813; H01L 29/7805

(57) ABSTRACT

A semiconductor substrate is fabricated in which only first and second n⁻-type epitaxial layers are stacked on an n⁺-type starting substrate, a front surface of the semiconductor substrate being a continuously flat surface from an active region to a chip end. In an edge termination region, as a voltage withstanding structure, a ring-shape FLR is provided in which p-type FLR regions concentrically surrounding a periphery of the active region are disposed apart from one another. The p-type FLR regions each have a layered structure configured by multiple p-type regions (partial FLRs) that are adjacent to one another in a depth direction and formed by performing ion implantation of a p-type impurity for each epitaxial growth of the first and the second n⁻-type epitaxial layers configuring the semiconductor substrate. A predetermined breakdown voltage is obtained by adjusting the number of stacked layers and impurity concentrations of the partial FLRs of the p-type FLR regions.

### CROSS REFERENCE TO RELATED APPLICATIONS

This application is based upon and claims the benefit of priority of the prior Japanese Patent Application No. 2020-150445, filed on Sep. 8, 2020, the entire contents of which are incorporated herein by reference.

### BACKGROUND OF THE INVENTION

### 1. Field of the Invention

Embodiments of the invention relate to a semiconductor device and a method of manufacturing a semiconductor device.

### 2. Description of the Related Art

Among power semiconductor devices that control high voltage and/or large current, there are several types such as bipolar transistors, insulated gate bipolar transistors (IGBTs), and metal oxide semiconductor field effect transistors (MOSFETs) that have insulated gates (MOS gates) having a 3-layer structure including a metal, an oxide film, and a semiconductor; these devices are selectively used according to an intended purpose.

For example, bipolar transistors and IGBTs have high current density compared to MOSFETs and can be adapted for large current but cannot be switched at high speeds. In particular, the limit of switching frequency is about several kHz for bipolar transistors and about several tens of kHz for IGBTs. On the other hand, MOSFETs have low current density compared to bipolar transistors and IGBTs and are difficult to adapt for large current but can be switched at high speeds up to about several MHz.

Further, a MOSFET, unlike an IGBT, has a built-in parasitic diode formed by pn junctions between an n⁻-type drift region and p-type base regions in a semiconductor substrate (semiconductor chip). Therefore, in an instance in which a MOSFET is used as a device for an inverter, this parasitic diode may be used to function as a diode (freewheeling diode (FWD)) for commutating load current flowing therethrough and a freewheeling diode for protecting itself.

While silicon (Si) is used as material for fabricating power semiconductor devices, there is a strong demand in the market for large-current, high-speed power semiconductor devices and thus, IGBTs and power MOSFETs have been intensively developed and improved, and the performance of power devices has substantially reached the theoretical limit determined by the material. Therefore, in terms of power semiconductor devices, semiconductor materials to replace silicon have been investigated and silicon carbide (SiC) has been focused on as a semiconductor material enabling fabrication (manufacture) of a next-generation power semiconductor device having low ON voltage, high-speed characteristics, and high-temperature characteristics.

SiC is a very stable material chemically, has a wide bandgap of 3 eV, and can be used very stably as a semiconductor material even at high temperatures. Further, SiC has a critical electric field strength that is at least ten times that of silicon and therefore, is expected to be a semiconductor material capable of sufficiently reducing ON resistance. Such characteristics of silicon carbide are also applicable to other semiconductors having a bandgap wider than a bandgap of silicon (hereinafter, wide bandgap semiconductors).

Further, in a MOS-type semiconductor device such as an IGBT or MOSFET, configuration of a trench gate structure in which, accompanying large current of a power semiconductor device, a channel (inversion layer) is formed along a sidewall of a trench, in a direction orthogonal to a front surface of a semiconductor chip is advantageous in terms of cost as compared to a planar gate structure in which the channel is formed along the front surface of the semiconductor chip. A reason for this is that unit cell (configuration unit of a device element) density per unit area may be increased with a trench gate structure and therefore, current density per unit area may be increased.

A rate of temperature rise relative to a volume occupied by the unit cells increases by an extent to which device current density is increased and therefore, to enhance discharge efficiency and stabilize reliability, a double-sided cooling structure is necessary. Further, a power semiconductor device that enhances reliability by having a high-function structure in which, on a single semiconductor substrate having a main semiconductor device element that is the MOSFET and performs a main operation of the power semiconductor device, high-function portions such as a current sensing portion, a temperature sensing portion, and an over-voltage protecting portion are disposed as circuit portions for protecting and controlling the main semiconductor device element.

Further, in a high-voltage semiconductor device, high voltage is applied to not only an active region in which a device element structure is formed, but also to an edge termination region that surrounds a periphery of the active region, and electric field concentrates in the edge termination region. Breakdown voltage of the semiconductor device is determined by an impurity concentration, thickness, and electric field strength of the semiconductor (drift region); destruction resistance is determined by these characteristics unique to the semiconductor and is constant spanning the active region and the edge termination region. Therefore, when electric field concentrates in the edge termination region and an electrical load exceeding the destruction resistance is applied to the edge termination region, destruction may occur in the edge termination region and thus, the overall breakdown voltage of the semiconductor device is determined by the breakdown voltage of the edge termination region.

In this regard, a structure that enhances the overall breakdown voltage of a semiconductor device is commonly known in which a voltage withstanding structure such as a junction termination extension (JTE) structure, a field limiting ring (FLR), etc. is disposed in the edge termination region, thereby mitigating or dispersing the electric field of the edge termination region, whereby the breakdown voltage of the edge termination region is enhanced. Further, a structure is commonly known in which a floating metal electrode in contact with a FLR is provided in the edge termination region as a field plate (FP).

A structure of a conventional silicon carbide semiconductor device is described. FIG. 20 is a cross-sectional view depicting a structure of the conventional silicon carbide semiconductor device. A conventional semiconductor device 230 depicted in FIG. 20 is a vertical MOSFET having a trench gate structure that has an active region 201 through which a main current (drift current) flows and an edge termination region 202 surrounding a periphery of the active region 201, in a semiconductor substrate (semiconductor chip) 210 containing silicon carbide. In the semiconductor substrate 210, an n⁻-type epitaxial layer 272 and a p-type epitaxial layer 273 are sequentially formed by epitaxial growth on an n⁺-type starting substrate 271 containing silicon carbide.

A portion of the p-type epitaxial layer 273 in the edge termination region 202 is removed by etching, forming a recess 291 in the semiconductor substrate 210, at a surface thereof in the edge termination region 202. A front surface of the semiconductor substrate 210, with the recess 291 as a boundary, has a first surface portion 210a on an inner side of the boundary (center-side of the semiconductor substrate 210) and a second surface portion 210b on an outer side of the boundary, closer to a chip end (end of the semiconductor substrate 210) than is the first surface portion 210a and recessed toward a drain electrode 252. The p-type epitaxial layer 273 is left in a mesa-shape in a center of the front surface (main surface including the p-type epitaxial layer 273) of the semiconductor substrate 210 due to the recess 291.

The first and the second surface portions 210a, 210b of the front surface of the semiconductor substrate 210 are formed by the p-type epitaxial layer 273 and the n⁻-type epitaxial layer 272, respectively. In the active region 201, in surface regions of the n⁻-type epitaxial layer 272 facing the p-type epitaxial layer 273, n-type current spreading regions 233 and first and second p⁺-type regions 261, 262 are each selectively provided. Further, in the active region, in surface regions of the semiconductor substrate 210, at the front surface thereof in the first surface portion 210a, n⁺-type source regions 235 and p⁺⁺-type contact regions 236 are each selectively provided in the p-type epitaxial layer 273.

The second p⁺-type regions 262 (262a), the p-type base regions 234 (234a), and the p⁺⁺-type contact regions 236 (236a) extend from the active region 201, to an intermediate region 203 between the active region 201 and the edge termination region 202, and reach a third surface portion (mesa edge of the recess) 210c connecting the first surface portion 210a and the second surface portion 210b of the front surface of the semiconductor substrate 210. In the edge termination region 202, in surface regions of the semiconductor substrate 210, at the front surface thereof in the second surface portion 210b, spatial modulator type FLRs 220 are configured by multiple p⁻-type regions 221 and multiple p⁻⁻-type regions 222 selectively provided in the n⁻-type epitaxial layer 272.

A spatial modulator type is structure in which a p-type impurity concentration per unit volume decreases stepwise with increasing proximity to the end of the substrate 210. In particular, the p⁻-type regions 221 are disposed separate from one another in a concentric shape surrounding a portion closer to the center of the substrate 210 than is an innermost one of the p⁻-type regions 221. The p⁻-type regions 221 are disposed in descending order of widths thereof with increasing proximity thereof to the end of the substrate 210 and an interval thereof with an adjacent p⁻-type region 221 on an inner side is narrow. An innermost one of the p⁻⁻-type regions 222 surrounds a periphery of all of the p⁻-type regions 221 and is disposed to be partially between all of the p⁻-type regions 221 that are adjacent to one another. The innermost one of the p⁻-type regions 221 and the innermost one of the p⁻⁻-type regions 222 are electrically connected to a p-type base region 234a via the second p⁺-type regions 262a.

The p⁻⁻-type regions 222 are disposed separate from one another, in a concentric shape surrounding a portion closer to the center of the substrate 210 than is an innermost one of the p⁻⁻-type regions 222. The p⁻-type regions 222 are disposed in descending order of widths thereof with increasing proximity thereof to the end of the substrate 210 and an interval thereof with an adjacent p⁻⁻-type region 222 on an inner side is narrow. The p⁻⁻-type regions 222, excluding the innermost one of the p⁻⁻-type regions 222, are disposed closer to the end of the substrate 210 and are the p⁻-type regions 221. An n⁻-type drift region 232 surrounds a periphery of all of the p⁻-type regions 221 and is partially disposed between the p⁻-type regions 221 that are adjacent to one another. In this manner, the spatial modulator type FLRs 220 are configured by adjusting widths and arrangements of the p⁻-type regions 221 and the p⁻⁻-type regions 222.

The n⁺-type source regions 235, the p⁺⁺-type contact regions 236, the n-type current spreading regions 233, the first and the second p⁺-type regions 261, 262, the p⁻-type regions 221, the p⁻⁻-type regions 222, and an n⁺-type channel region 223 are diffused regions formed by ion implantation. Portions of the p-type epitaxial layer 273 excluding the n⁺-type source regions 235 and the p⁺⁺-type contact regions 236 are p-type base regions 234. A portion of the n⁻-type epitaxial layer 272 excluding the n-type current spreading regions 233, the first and the second p⁺-type regions 261, 262, the p⁻-type regions 221, the p⁻-type regions 222, and the n⁺-type channel region 223 is the n⁻-type drift region 232.

Reference numeral 231 is an n⁺-type drain region configured by the n⁺-type starting substrate 271. Reference numerals 238, 239, 240, 240a, 241, 281, 282, and 283 are gate insulating films, gate electrodes, an interlayer insulating film, contact holes, metal silicide films, a field oxide film, a gate polysilicon wiring layer, and a gate metal wiring layer. Reference numerals 242, 243, 244, and 245 are metal films configuring a barrier metal 246. Reference numerals 248 and 249 are plating films and terminal pins configuring a wiring structure on a source pad 247. Reference numerals 250 and 251 are protective films (passivation films).

As a conventional semiconductor device, a structure has been proposed in which, in the edge termination region, an outermost dividing trench and multiple terminal trenches filled with an insulating material are formed penetrating through p-type base regions and reaching an n-type drift region, the device having p-type spreading regions surrounding bottoms of these trenches, respectively (for example, refer to Japanese Patent No. 5206248). In Japanese Patent No. 5206248, the terminal trenches are disposed at intervals connecting a depletion layer that spreads from the active region toward an outer side when a MOSFET is OFF, whereby high breakdown voltage is sustained, and an interval between the dividing trench and an outermost one of the terminal trenches is set as an interval that does not connect the depletion layer, whereby an occurrence of leak current is prevented.

Further, as a conventional silicon carbide semiconductor device, a device has been proposed in which silicon carbide layers constituting an n⁻-type drift region and a p-type base region extend from the active region to an edge termination region, and as an electric field mitigating layer, a portion of the p-type base region in the edge termination region has a relatively thinner thickness due to a recess formed at a front surface of a semiconductor substrate in the edge termination region (for example, refer to Japanese Patent No. 5691259). In Japanese Patent No. 5691259, the portion of p-type base region extended into the edge termination region is regarded as the electric field mitigating layer, whereby the electric field mitigating layer has a structure without curved portions and without material discontinuities with the n⁻-type drift region, and breakdown voltage of the semiconductor device is enhanced.

Further, as another conventional silicon carbide semiconductor device, a device has been proposed in which a trench of a same depth as that of gate trenches is formed in an edge termination region, and a FLR is configured by a floating p-type region constituted by a p-type silicon carbide layer epitaxially grown having a U-shaped cross-section along an inner wall of the trench (for example, refer to Japanese Laid-Open Patent Publication No. 2005-340250. In Japanese Laid-Open Patent Publication No. 2005-340250, when surge voltage is applied to a drain electrode, a depletion layer spreads from the FLR, and without unevenness of electric field applied to the active region, spreads to the edge termination region, mitigating electric field at an end of the active region, whereby the breakdown voltage of the active region is enhanced.

Further, as another conventional silicon carbide semiconductor device, a device has been proposed in which a FLR is configured by at least one p-type region formed by ion implantation, a border between an n⁺-type silicon carbide layer forming an front surface of a semiconductor substrate and an n⁻-type silicon carbide layer adjacent to the n⁺-type silicon carbide layer in a depth direction is positioned closer to the front surface of the semiconductor substrate than is a back-electrode-facing-end of the p-type regions configuring the FLRs (for example, refer to Japanese Patent No. 5628462). In Japanese Patent No. 5628462, the n⁺-type silicon carbide layer is provided in a surface region of the semiconductor substrate, at the front surface thereof, whereby breakdown voltage variation that occurs according to the thickness of the silicon carbide layer disappearing from the front surface of the semiconductor substrate is suppressed.

Further, as another conventional silicon carbide semiconductor device, a device has been proposed in which multiple p-type regions configuring FLRs are respectively configured by a high-concentration region including a peak concentration position thereof near a front surface of a semiconductor substrate and a low-concentration region surrounding a side surface and directly beneath the high-concentration region; and a p-type impurity concentration distribution decreases with increasing proximity to an n-type drift region from the peak concentration position (for example, refer to Japanese Laid-Open Patent Publication No. 2018-067690). In Japanese Laid-Open Patent Publication No. 2018-067690, in an outermost one of the p-type regions configuring the FLRs, a width of the low-concentration region surrounding an outer peripheral side surface of the high-concentration region is made relatively wide, application of electric field to the high-concentration region is suppressed, and an occurrence of leak current is suppressed.

Further, as another conventional silicon carbide semiconductor device, a device has been proposed in which p⁺-type regions forming pn junctions with an n⁻-type drift region closer to a drain electrode than are bottoms of gate trenches are disposed separate from the gate trenches, at positions facing the bottoms of the gate trenches in the depth direction and between adjacent gate trenches of the gate trenches (for example, refer to International Publication No. WO 2017/064949). In International Publication No. WO 2017/064949, electric field applied to gate insulating films at the bottoms of the gate trenches is mitigated by the p⁺-type regions forming the pn junctions with the n⁻-type drift region closer to the drain electrode than are the bottoms of the gate trenches, whereby even in an instance in which silicon carbide is used as a semiconductor material, high breakdown voltage is facilitated.

### SUMMARY OF THE INVENTION

According to an embodiment of the invention, a semiconductor device having an active region through which a main current flows and a termination region surrounding a periphery of the active region, the semiconductor device, comprising: a semiconductor substrate containing a semiconductor having a bandgap wider than a bandgap of silicon, the semiconductor substrate having a first main surface and a second main surface opposite to each other, the semiconductor substrate including a first-conductivity-type epitaxial layer that forms the first main surface of the semiconductor substrate; a first semiconductor region of a first conductivity type, provided in the semiconductor substrate; a second semiconductor region of a second conductivity type, selectivity provided in the semiconductor substrate in the active region, between the first main surface of the semiconductor substrate and the first semiconductor region; a device element structure formed in the semiconductor substrate in the active region, the device element structure having a pn junction between the second semiconductor region and the first semiconductor region; a first electrode electrically connected to the second semiconductor region; a second electrode provided on the second main surface of the semiconductor substrate; and a plurality of second-conductivity-type voltage withstanding regions each selectively provided in the semiconductor substrate in the termination region, between the first main surface of the semiconductor substrate and the first semiconductor region, separate from the device element structure, the second-conductivity-type voltage withstanding regions concentrically surrounding the periphery of the active region to form concentric circles in a plan view of the semiconductor device, and being each provided separate from one another in a radial direction of the concentric circles. The first main surface of the semiconductor substrate is a flat surface spanning both the active region and the termination region. The second semiconductor region and the second-conductivity-type voltage withstanding regions are diffused regions, in each of which an impurity of the second conductivity type is introduced in a respective region selectively provided in a first portion of the first-conductivity-type epitaxial layer. The first semiconductor region is a second portion of the first-conductivity-type epitaxial layer excluding the first portion of the first-conductivity-type epitaxial layer, the second portion including regions, between any two of the second-conductivity-type voltage withstanding regions that are adjacent to each other, from bottoms of the second-conductivity-type voltage withstanding regions to the first main surface of the semiconductor substrate.

Objects, features, and advantages of the present invention are specifically set forth in or will become apparent from the following detailed description of the invention when read in conjunction with the accompanying drawings.

### BRIEF DESCRIPTION OF THE DRAWINGS

FIG. 1 is a plan view of a layout when a semiconductor device according to a first embodiment is viewed from a front side of a semiconductor substrate.

FIG. 2 is a cross-sectional view of a structure along cutting line A-A′ in FIG. 1.

FIG. 3 is a cross-sectional view of other examples of the structure along cutting line A-A′ in FIG. 1.

FIG. 4 is a cross-sectional view of other examples of the structure along cutting line A-A′ in FIG. 1.

FIG. 5 is a cross-sectional view of another example of the semiconductor device according to the first embodiment.

FIG. 6 is a cross-sectional view of another example of the semiconductor device according to the first embodiment.

FIG. 7 is a cross-sectional view of a state of the semiconductor device according to the first embodiment during manufacture.

FIG. 8 is a cross-sectional view of a state of the semiconductor device according to the first embodiment during manufacture.

FIG. 9 is a cross-sectional view of a state of the semiconductor device according to the first embodiment during manufacture.

FIG. 10 is a cross-sectional view of a state of the semiconductor device according to the first embodiment during manufacture.

FIG. 11 is a cross-sectional view of a state of the semiconductor device according to the first embodiment during manufacture.

FIG. 12 is a cross-sectional view of a state of the semiconductor device according to the first embodiment during manufacture.

FIG. 13 is a cross-sectional view of a state of the semiconductor device according to the first embodiment during manufacture.

FIG. 14 is a cross-sectional view of a state of the semiconductor device according to the first embodiment during manufacture.

FIG. 15 is a cross-sectional view of a state of the semiconductor device according to the first embodiment during manufacture.

FIG. 16 is a cross-sectional view of a state of the semiconductor device according to the first embodiment during manufacture.

FIG. 17 is a cross-sectional view of an example of a voltage withstanding structure of a semiconductor device according to a second embodiment.

FIG. 18 is a cross-sectional view of an example of the voltage withstanding structure of the semiconductor device according to the second embodiment.

FIG. 19 is a cross-sectional view of an example of the voltage withstanding structure of the semiconductor device according to the second embodiment.

FIG. 20 is a cross-sectional view depicting a structure of a conventional silicon carbide semiconductor device.

### DETAILED DESCRIPTION OF THE INVENTION

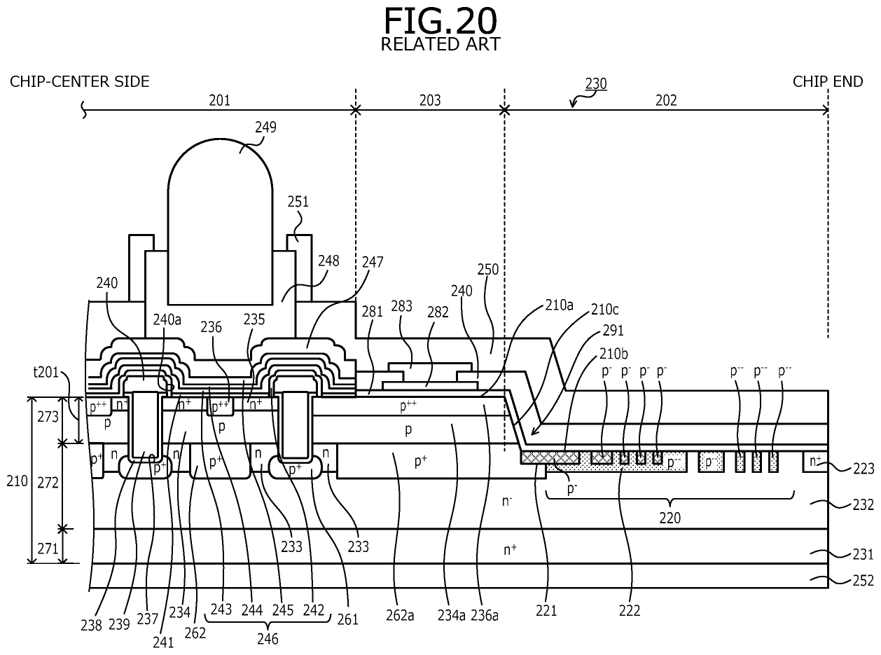

First, problems associated with conventional techniques are discussed. As described above, in an instance in which the FLRs 220 are a spatial modulator type (refer to FIG. 20), overlapping of ion implantations is complicated, and positioning (alignment) of ion implantation masks used in forming the p⁻-type regions 221 and the p⁻⁻-type regions 222 is difficult. When the semiconductor device 230 is OFF, high voltage applied in the edge termination region 202 in a horizontal direction (a direction parallel to the front surface of the semiconductor substrate 210) is born by the pn junctions between the p⁻-type regions 221, the p⁻⁻-type regions 222, and the n⁻-type drift region 232 and therefore, when positioning accuracy of the ion implantation masks is low, the degree of completeness of the FLRs 220 decreases and reliability of the semiconductor device 230 decreases.

Embodiments of a semiconductor device and a method of manufacturing a semiconductor device according to the present invention will be described in detail with reference to the accompanying drawings. In the present description and accompanying drawings, layers and regions prefixed with n or p mean that majority carriers are electrons or holes. Additionally, + or − appended to n or p means that the impurity concentration is higher or lower, respectively, than layers and regions without + or −. In the description of the embodiments below and the accompanying drawings, main portions that are identical will be given the same reference numerals and will not be repeatedly described.

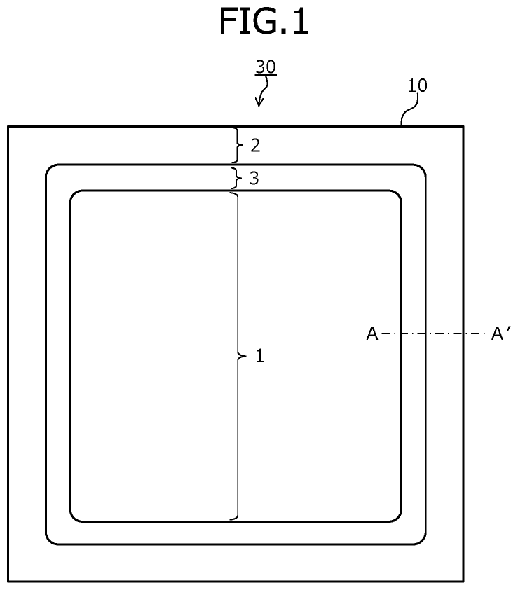

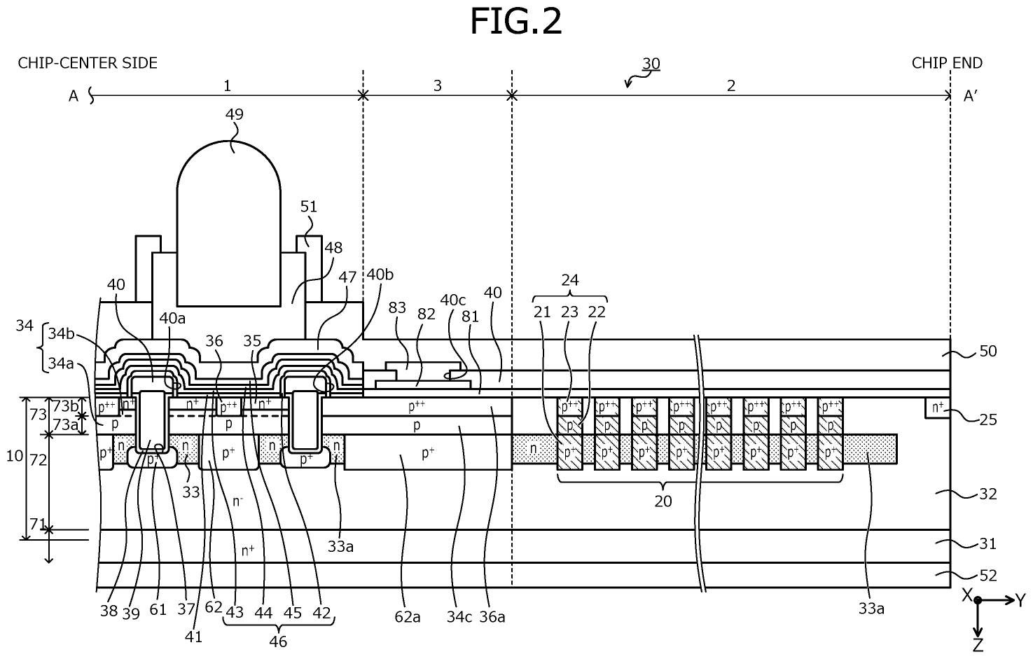

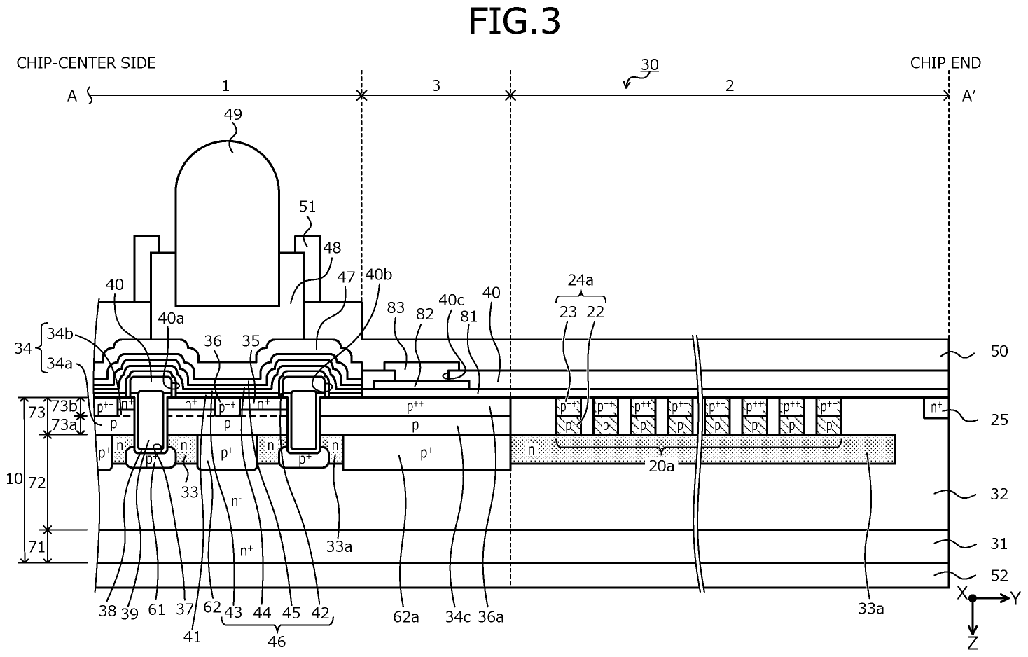

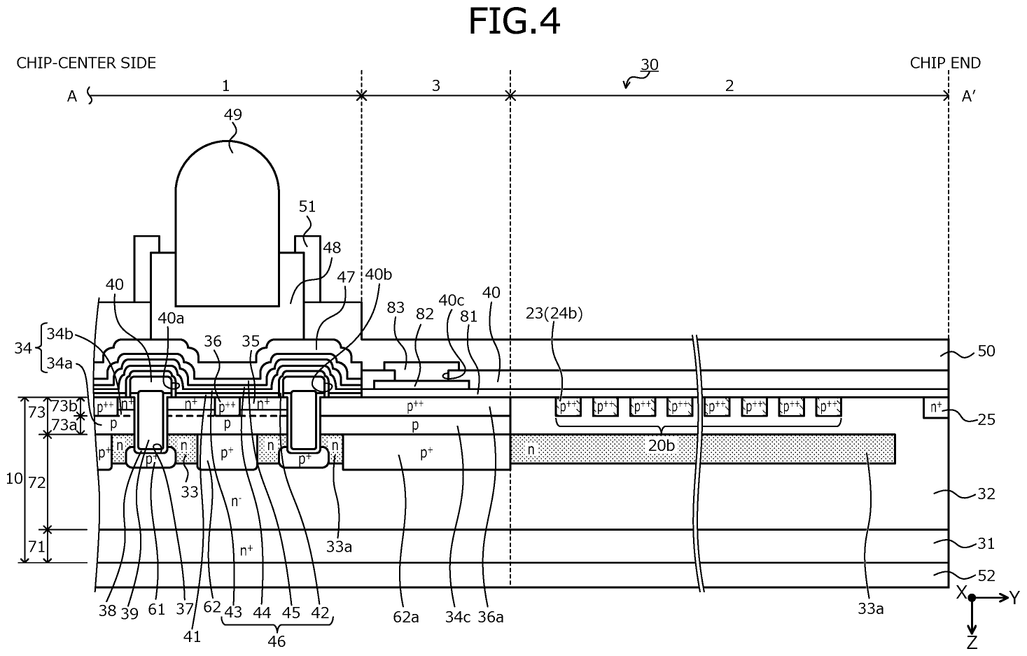

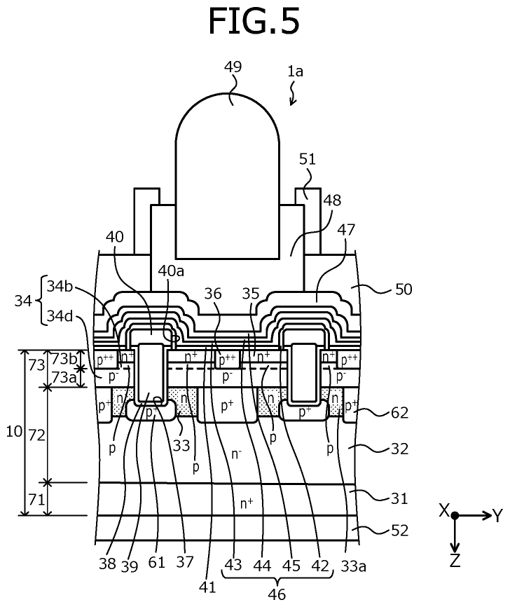

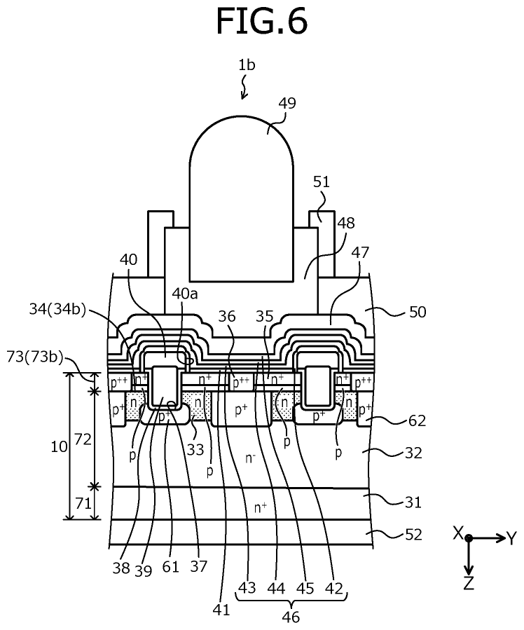

A structure of a semiconductor device according to a first embodiment is described taking a vertical MOSFET having a trench gate structure as an example. FIG. 1 is a plan view of a layout when the semiconductor device according to the first embodiment is viewed from a front side of a semiconductor substrate. FIG. 2 is a cross-sectional view of the structure along cutting line A-A′ in FIG. 1. FIGS. 3 and 4 are cross-sectional views of other examples of the structure along cutting line A-A′ in FIG. 1. FIGS. 5 and 6 are cross-sectional views of other examples of the semiconductor device according to the first embodiment. FIGS. 5 and 6 depict other examples of a MOSFET unit cell of active regions 1a, 1b.

A semiconductor device 30 according to the first embodiment depicted in FIGS. 1 and 2 is a vertical MOSFET having a trench gate structure (device element structure) in an active region 1 of a semiconductor substrate (the semiconductor chip) 10 that contains silicon carbide (SiC), and the semiconductor device 30 has a field limiting ring (FLR) 20 as a voltage withstanding structure in an edge termination region 2 that surrounds a periphery of the active region 1. The active region 1 is a region through which main current (drift current) flows when the MOSFET is ON. In the active region 1, multiple unit cells (constituent units of a device element) of the MOSFET each having a similar structure are disposed adjacent to one another.

The active region 1 has a substantially rectangular shape in a plan view thereof and is disposed in substantially a center (chip center) of the semiconductor substrate 10. The active region 1 is a region further inward (toward the chip center) than is an outer (relatively closer to the chip end) sidewall (side surface of an interlayer insulating film 40) of an outermost contact hole 40b. An intermediate region 3 between the active region 1 and the edge termination region 2 is adjacent to the active region 1 and surrounds the periphery of the active region 1. A border between the intermediate region 3 and the edge termination region 2 is a border between an n⁻-type drift region (first semiconductor region) 32 and respective outer ends of a later-described outer peripheral p-type base region 34c and outer peripheral p⁺-type region 62a.

The edge termination region 2 is a region between the active region 1 and the end of the semiconductor substrate 10 (chip end), surrounds the periphery of the active region 1 via the intermediate region 3, and has a function of mitigating electric field of the front side of the semiconductor substrate 10 and sustaining a breakdown voltage. In the edge termination region 2, the field limiting ring (FLR) 20 is disposed, as a voltage withstanding structure, in the semiconductor substrate 10, at the front surface thereof. Even when avalanche current is caused by the pn junctions and current between a source and drain increases, the breakdown voltage is a voltage limit at which the current between the source and drain does not further increase.

In the semiconductor substrate 10, first and second n⁻-type epitaxial layers (first-conductivity-type epitaxial layers) 72, 73 are sequentially stacked on a front surface of an n⁺-type starting substrate 71 that contains silicon carbide. A main surface including a second n⁻-type epitaxial layer 73 (surface of the second n⁻-type epitaxial layer 73) of the semiconductor substrate 10 is regarded as a front surface and a main surface thereof including the n⁺-type starting substrate 71 (back surface of the n⁺-type starting substrate 71) is regarded as a back surface. The n⁺-type starting substrate 71 is an n⁺-type drain region 31. In the active region 1, MOS gates are provided in the semiconductor substrate 10, at the front side thereof.

The MOS gates are configured by p-type base region (second semiconductor regions) 34, n⁺-type source regions (third semiconductor regions) 35, p⁺⁺-type contact regions (fourth semiconductor regions) 36, gate trenches 37, gate insulating films 38, and gate electrodes 39. A portion on an outer side (a portion of the outer peripheral p-type base region 34c described hereinafter) of an outermost peripheral one of the gate trenches 37 is configured to be free of the n⁺-type source regions 35. The gate trenches 37 penetrate through the second n⁻-type epitaxial layer 73 in a depth direction Z from the front surface of the semiconductor substrate 10 and reach inside the first n⁻-type epitaxial layer 72.

The gate trenches 37, in the active region 1, extend in a striped pattern in a first direction X parallel to the front surface of the semiconductor substrate 10 and reach the intermediate region 3. In the gate trenches 37, the gate electrodes 39 are respectively provided via the gate insulating films 38. The p-type base region 34, the n⁺-type source regions 35 and the p⁺⁺-type contact regions 36 (including the outer peripheral p-type base region 34c and an outer peripheral p⁺⁺-type contact region 36a described hereinafter) are diffusion regions selectively formed in the second n⁻-type epitaxial layer 73.

The p-type base region 34, in the depth direction Z, reaches a border between the second n⁻-type epitaxial layer 73 and the first n⁻-type epitaxial layer 72. The p-type base region 34 may terminate at a position shallower from the front surface of the semiconductor substrate 10 than are bottoms of the gate trenches 37 or may reach inside the first n⁻-type epitaxial layer 72. The p-type base region 34 is provided in an entire area of the active region 1 and the intermediate region 3. An outer peripheral portion (hereinafter, outer peripheral p-type base region) 34c of the p-type base region 34 surrounds a periphery of a center-side portion of the active region 1 in a substantially rectangular shape.

The outer peripheral p-type base region 34c is a portion of the p-type base region 34 closer to the chip end in the first direction X (longitudinal direction of the gate trenches 37) than are the n⁺-type source regions 35 and closer to the chip end than is the outermost peripheral one of the gate trenches 37 in a second direction Y (lateral direction of the gate trenches 37) parallel to the front surface of the semiconductor substrate 10 and orthogonal to the first direction X. The n⁺-type source regions 35 and the p⁺⁺-type contact regions 36 are each selectively provided between the front surface of the semiconductor substrate 10 and the p-type base region 34, in contact with the p-type base region 34.

The n⁺-type source regions 35 and the p⁺⁺-type contact regions 36 are exposed at the front surface of the semiconductor substrate 10. Here, being exposed at the front surface of the semiconductor substrate 10 means that the n⁺-type source regions 35 and the p⁺⁺-type contact regions 36 are in contact with later-described NiSi films 41 through contact holes 40a in the interlayer insulating film 40 described hereinafter. Between the gate trenches 37 that are adjacent to one another, the n⁺-type source regions 35 and the p⁺⁺-type contact regions 36 are disposed repeatedly alternating one another in the first direction X that is the same direction in which the gate electrodes 39 extend (not depicted).

The p⁺⁺-type contact regions 36 are disposed separate from the gate trenches 37, scattered in the first direction X. The n⁺-type source regions 35 are in contact with the gate insulating films 38 at sidewalls of the gate trenches 37. The n⁺-type source regions 35, for example, between the gate trenches 37 that are adjacent to one another, form a ladder-like shape surrounding peripheries of the p⁺⁺-type contact regions 36 in a plan view thereof. In this instance, the n⁺-type source regions 35 have portions extending along the sidewalls of the gate trenches 37 in the first direction X and portions sandwiched between the p⁺⁺-type contact regions 36 adjacent to one another in the first direction X.

Further, one of the p⁺⁺-type contact regions 36 (hereinafter, the outer peripheral p⁺⁺-type contact region 36a) is provided in contact with the outer peripheral p-type base region 34c in an entire area between the front surface of the semiconductor substrate 10 and the outer peripheral p-type base region 34c, and is exposed at the front surface of the semiconductor substrate 10. Here, being exposed at the front surface of the semiconductor substrate 10 means that the outer peripheral p⁺⁺-type contact region 36a is in contact with one of the NiSi films 41 through the outermost contact hole 40b. The outer peripheral p⁺⁺-type contact region 36a is in contact with the gate insulating film 38 of the outermost peripheral one of the gate trenches 37 at the sidewall thereof closest to the chip end.

The p⁺⁺-type contact regions 36 and the outer peripheral p⁺⁺-type contact region 36a may be omitted. In this instance, instead of the p⁺⁺-type contact regions 36 and the outer peripheral p⁺⁺-type contact region 36a, the p-type base region 34 and the outer peripheral p-type base region 34c both reach and are exposed at the front surface of the semiconductor substrate 10. In the semiconductor substrate 10, the n⁻-type drift region 32 is provided in contact with and between the p-type base region 34, the outer peripheral p-type base region 34c, and the n⁺-type drain region 31 (the n⁺-type starting substrate 71).

An n-type current spreading region 33 may be provided in contact with and between the p-type base region 34, the outer peripheral p-type base region 34c, and the n⁻-type drift region 32. The n-type current spreading region 33 is a so-called current spreading layer (CSL) that reduces carrier spreading resistance. The n-type current spreading region 33 extends having a substantially uniform thickness from the active region 1 to the edge termination region 2 and an outer peripheral portion thereof (first-conductivity-type region, hereinafter, outer-peripheral n-type current spreading region) 33a terminates between the FLR 20 and a later-described n⁺-type stopper region 25.

Further, in the semiconductor substrate 10, at positions closer to the n⁺-type drain region 31 than are the bottoms of the gate trenches 37, first and second p⁺-type regions (second-conductivity-type high-concentration regions) 61, 62 that mitigate electric field applied to the bottoms of the gate trenches 37 are provided. In the first direction X that is the same direction in which the gate trenches 37 extend, the first and the second p⁺-type regions 61, 62 extend in linear shapes having a length substantially the same as that of the gate trenches 37. The first and the second p⁺-type regions 61, 62 may have substantially the same distance to the n⁺-type drain region 31 in the depth direction Z and this depth position may be variously changed.

For example, the first and the second p⁺-type regions 61, 62 may terminate in the n-type current spreading region 33 and peripheries thereof may be surrounded by the n-type current spreading region 33 (not depicted), or the first and the second p⁺-type regions 61, 62 may be in contact with the n⁻-type drift region 32 and terminate at a border between the n-type current spreading region 33 and the n⁻-type drift region 32 (not depicted). Alternatively, the first and the second p⁺-type regions 61, 62 may extend to positions closer to the n⁺-type drain region 31 than is the n-type current spreading region 33 in the depth direction Z and may terminate in the n⁻-type drift region 32 (refer to FIG. 2).

The first p⁺-type regions 61 (first high-concentration regions) are provided separate from the p-type base region 34 and face the bottoms of the gate trenches 37 in the depth direction Z. The first p⁺-type regions 61 may be wider than the gate trenches 37 and may face bottom corner portions of the gate trenches 37. The first p⁺-type regions 61 may reach the bottoms of the gate trenches 37 and may be in contact with the gate insulating films 38 at the bottoms of the gate trenches 37 (or from the bottoms to the bottom corner portions). The bottom corner portions of the gate trenches 37 are portions connecting the bottoms and the sidewalls of the gate trenches 37.

While the first p⁺-type regions 61 may have a floating potential (FIG. 2), the first p⁺-type regions 61 may be electrically connected to the second p⁺-type regions 62 at a predetermined portion and fixed to a potential of a source electrode (first electrode). While not depicted, in an instance in which the first p⁺-type regions 61 are fixed to the potential of the source electrode, the first p⁺-type regions 61 suffice to be partially connected to the second p⁺-type regions (second high-concentration regions) 62 by disposing another p⁺-type region (not depicted) at a predetermined location between the first and the second p⁺-type regions 61, 62 or instead of another p⁺-type region, by extending a portion of the first p⁺-type regions 61 toward the second p⁺-type regions 62.

The first p⁺-type regions 61 are fixed to the potential of the source electrode, whereby holes (positive holes) generated in the n⁻-type drift region 32 when avalanche breakdown occurs due to pn junctions between the first p⁺-type regions 61 and the n-type current spreading region 33 or the n⁻-type drift region 32 (or both) may be efficiently discharged to the source electrode. As a result, when the MOSFET is OFF, at the bottoms of the gate trenches 37, electric field applied to the gate insulating films 38 is assuredly mitigated and reliability of the semiconductor device 30 may be enhanced.

Between the gate trenches 37 that are adjacent to one another, the second p⁺-type regions 62 are provided separate from the first p⁺-type regions 61 and the gate trenches 37, and adjacent to the p-type base region 34 in the depth direction Z. Further, one of the second p⁺-type regions 62 (hereinafter, the outer peripheral p⁺-type region 62a) is provided closer to the chip end than is the outermost peripheral one of the gate trenches 37, separate from the first p⁺-type regions 61 and the outermost peripheral one of the gate trenches 37, and adjacent to the outer peripheral p-type base region 34c in the depth direction Z. The outer peripheral p⁺-type region 62a extends toward the chip end from the active region 1 and is provided in an entire area of the intermediate region 3.

The outer peripheral p⁺-type region 62a surrounds the periphery of the center-side portion of the active region 1 in a substantially rectangular shape, and connects ends of all of the first and the second p⁺-type regions 61, 62. While FIG. 2 depicts a configuration in which in the active region 1, the second p⁺-type regions 62 penetrate through the n-type current spreading region 33 in the depth direction Z, whereby in the intermediate region 3, the outer peripheral p⁺-type region 62a penetrates through the outer-peripheral n-type current spreading region 33a in the depth direction Z, the outer peripheral p⁺-type region 62a may terminate in the outer-peripheral n-type current spreading region 33a in the depth direction Z.

The n-type current spreading region 33, the outer-peripheral n-type current spreading region 33a, the first and the second p⁺-type regions 61, 62, and the outer peripheral p⁺-type region 62a are diffusion regions formed by ion implantation in the first n⁻-type epitaxial layer 72, in the active region 1 and the intermediate region 3. In the active region 1 and the intermediate region 3, a portion of the first n⁻-type epitaxial layer 72 excluding the diffusion regions formed by ion implantation is the n⁻-type drift region 32. The n⁻-type drift region 32 extends from the active region 1 to the chip end.

The interlayer insulating film 40 is provided in substantially an entire area of the front surface of the semiconductor substrate 10 and covers the gate electrodes 39 of all of the unit cells of the MOSFET. In the active region 1, the contact holes 40a, 40b that penetrate through the interlayer insulating film 40 in the depth direction Z are provided. The contact holes 40a, for example, are provided between the gate trenches 37 that are adjacent to one another; the contact holes 40a extend in a linear shape in the first direction X that is the same direction in which the gate trenches 37 extend. In the contact holes 40a, the n⁺-type source regions 35 and the p⁺⁺-type contact regions 36 are exposed.

The contact hole 40b, for example, is provided in a substantially rectangular shape surrounding the periphery of the center-side portion of the active region 1. In the contact hole 40b, the outer peripheral p⁺⁺-type contact region 36a is exposed. The nickel silicide (NixSiy, where, “x” and “y” are integers, hereinafter, collectively “NiSi”) films 41, respectively in the contact holes 40a, 40b, are in ohmic contact with the semiconductor substrate 10 and are electrically connected to the n⁺-type source regions 35, the p⁺⁺-type contact regions 36, and the outer peripheral p⁺⁺-type contact region 36a.

In an instance in which the p⁺⁺-type contact regions 36 and the outer peripheral p⁺⁺-type contact region 36a are omitted, instead of the p⁺⁺-type contact regions 36 and the outer peripheral p⁺⁺-type contact region 36a, the p-type base region 34 and the outer peripheral p-type base region 34c are exposed in the contact holes 40a, 40b, respectively, and are electrically connected to the NiSi films 41. In an entire area of a surface of the interlayer insulating film 40 and surfaces of the NiSi films 41 in the active region 1, a barrier metal 46 is provided along the surface of the interlayer insulating film 40 and the surfaces of the NiSi films 41.

The barrier metal 46 has a function of preventing interaction between metal films of the barrier metal 46 or between regions facing one another across the barrier metal 46. The barrier metal 46 may have a layered structure in which, for example, a first titanium nitride (TiN) film 42, a first Ti film 43, a second TiN film 44, and a second Ti film 45 are sequentially stacked. The first TiN film 42 covers an entire area of the surface of the interlayer insulating film 40 in the active region 1. The first Ti film 43 is provided in an entire area of a surface of the first TiN film 42 and the surfaces of the NiSi films 41.

The second TiN film 44 is provided in an entire area of a surface of the first Ti film 43. The second Ti film 45 is provided in an entire area of a surface of the second TiN film 44. An Al electrode film 47 is provided in an entire area of a surface of the second Ti film 45. The aluminum (Al) electrode film 47 is electrically connected to the n⁺-type source regions 35, the p⁺⁺-type contact regions 36, and the outer peripheral p⁺⁺-type contact region 36a, via the barrier metal 46 and the NiSi films 41. The Al electrode film 47 and the barrier metal 46 terminate closer to the chip center than is a later-described gate metal wiring layer 83 of the intermediate region 3.

The Al electrode film 47 may be, for example, an Al film, an aluminum-silicon (Al—Si) film, or an aluminum-silicon-copper (Al—Si—Cu) film having a thickness of about 5 μm. The Al electrode film 47, the barrier metal 46, and the NiSi films 41 function as the source electrode. First ends of terminal pins 49 are bonded on the Al electrode film 47, via plating films 48 and a solder layer (not depicted). Second ends of the terminal pins 49 are bonded to a metal bar (not depicted) disposed facing the front surface of the semiconductor substrate 10.

Further, the second ends of the terminal pins 49 are exposed outside a case (not depicted) in which the semiconductor substrate 10 is mounted, and are electrically connected to an external device (not depicted). The terminal pins 49 are soldered to the plating films 48 in a substantially upright state with respect to the front surface of the semiconductor substrate 10. The terminal pins 49 are wiring members having a round, rod-like shape (cylinder shape) having a predetermined diameter corresponding to current capability of the MOSFET and are connected to an external ground (minimum potential). The terminal pins 49 are external connection terminals that lead out potential of the Al electrode film 47 to an external destination.

First and second protective films 50, 51 are, for example, polyimide films. The first protective film 50 covers portions of a surface of the Al electrode film 4 other than the plating films 48. The first protective film 50 extends to the chip end so as to cover the Al electrode film 47, the interlayer insulating film 40, and the gate metal wiring layer 83, and function as a passivation film. A portion of the Al electrode film 47 exposed in an opening of the first protective film 50 is a source pad. The second protective films 51 cover boundaries between the plating films 48 and the first protective film 50.

The front surface of the semiconductor substrate 10 is a continuously flat surface from the active region 1 to chip end and in the edge termination region 2, is free of a recess such as the recess 291 in the conventional structure (refer to FIG. 20). In other words, an entire area of the front surface of the semiconductor substrate 10 is formed by the second n⁻-type epitaxial layer 73. In the intermediate region 3, in the semiconductor substrate 10, at the front surface thereof, the outer peripheral p-type base region 34c and the outer peripheral p⁺⁺-type contact region 36a formed by ion implantation are selectively provided in the second n⁻-type epitaxial layer 73.

The outer peripheral p-type base region 34c is fixed to the potential of the source electrode and has a function of making electric field at the front surface of the semiconductor substrate 10 uniform and thereby, enhancing the breakdown voltage. The outer peripheral p⁺⁺-type contact region 36a is an extraction region for pulling out holes from the n⁻-type drift region 32 of the intermediate region 3 and the edge termination region 2, to the source electrode when the MOSFET is OFF. Further, in the intermediate region 3, as described above, the outer-peripheral n-type current spreading region 33 and the outer peripheral p⁺-type region 62a formed by ion implantation are provided in the first n⁻-type epitaxial layer 72.

In the intermediate region 3 and the edge termination region 2, on the front surface of the semiconductor substrate 10, an insulating layer in which a field oxide film 81 and the interlayer insulating film 40 are sequentially stacked is provided. The insulating layer extends outward from the intermediate region 3 to the chip end, and in the intermediate region 3 and the edge termination region 2, covers an entire area of the front surface of the semiconductor substrate 10. In the intermediate region 3, between the field oxide film 81 and the interlayer insulating film 40, a gate polysilicon wiring layer 82 is provided facing the outer peripheral p⁺⁺-type contact region 36a in the depth direction Z.

The gate metal wiring layer 83 is in contact with the gate polysilicon wiring layer 82, via a contact hole 40c opened in the interlayer insulating film 40. The gate polysilicon wiring layer 82 and the gate metal wiring layer 83 are a gate runner surrounding the periphery of the center-side portion of the active region 1 in a substantially rectangular shape. The gate metal wiring layer 83 faces ends of the gate trenches 37 in the depth direction Z. The gate metal wiring layer 83 is in contact with the gate electrodes 39 at the ends of the gate trenches 37, and electrically connects all of the gate electrodes 39 of the active region 1 and the gate pad (not depicted).

In the intermediate region 3, at the front surface of the semiconductor substrate 10, the outer peripheral p⁺⁺-type contact region 36a extending from the active region 1 is exposed. In the edge termination region 2, at the front surface of the semiconductor substrate 10, uppermost later-described partial FLRs (third regions 23) configuring the FLR 20, and the n⁻-type drift region 32 are exposed. In the intermediate region 3 and the edge termination region 2, being exposed at the front surface of the semiconductor substrate 10 means being provided in the semiconductor substrate 10, at the front surface thereof and being in contact with the field oxide film 81, in the intermediate region 3 and the edge termination region 2.

In the edge termination region 2, the FLR 20 is provided as a voltage withstanding structure. The FLR 20 is a ring-shape junction structure in which multiple floating p-type regions (hereinafter, p-type FLR regions (second-conductivity-type voltage withstanding regions)) 24 of an identical configuration surround the periphery of the active region 1 in a concentric shape, via the intermediate region 3. High electric field applied in the edge termination region 2 in the horizontal direction (direction parallel to the front surface of the semiconductor substrate 10) when the MOSFET (the semiconductor device 30) is OFF, is born by pn junctions between the p-type FLR regions 24 and the n⁻-type drift region 32, securing a predetermined breakdown voltage of the edge termination region 2.

The p-type FLR regions 24, as described hereinafter, are configured by multiple p-type regions (hereinafter, “partial FLRs” (second-conductivity-type regions)) adjacent to one another in the depth direction Z and having substantially a same width (width in direction of normal); the p-type FLR regions 24 are formed by performing ion implantation of a p-type impurity each time epitaxial growth is performed forming the first and the second n⁻-type epitaxial layers 72 (72a), 73 (73a, 73b) of a respective predetermined thickness; and the p-type FLR regions 24 have an impurity concentration distribution that varies stepwise in the depth direction Z. The direction of a normal is a direction orthogonal to a direction in which the p-type FLR regions 24 extend in the ring-shape (a direction from a chip-center side to the chip end). Respective impurity concentrations and depth positions of the partial FLRs configuring the p-type FLR regions 24 are adjusted, thereby establishing the predetermined breakdown voltage of the edge termination region 2.

A total impurity concentration of one set of the partial FLRs (for example, in FIG. 2, a 3-layer structure of first, second, and third regions 21, 22, 23) adjacent to one another in the depth direction Z suffices to satisfy a predetermined impurity concentration of one of the p-type FLR regions 24 configured by these partial FLRs. The partial FLRs configuring the p-type FLR regions 24, as described hereinafter, may be formed concurrently with the p-type regions configuring the MOSFET of the active region 1 and formed by ion implantation in each of the first and the second n⁻-type epitaxial layers 72 (72a), 73 (73a,73b) that are deposited sequentially and have predetermined thicknesses.

For example, the first to third regions (partial FLRs) 21 to 23 adjacent to one another in the depth direction Z and configuring one of the p-type FLR regions 24 may be formed respectively and concurrently with the second p⁺-type regions 62, the p-type base region 34, and the p⁺⁺-type contact regions 36 of the active region 1 (refer to FIG. 2). Further, the partial FLRs adjacent to one another in the depth direction Z and configuring one of the p-type FLR regions 24 may be formed at a different timing from the formation of the p-type regions configuring the MOSFET of the active region 1. The p-type FLR regions 24 may terminate in the outer-peripheral n-type current spreading region 33a (not depicted).

A depth of the p-type FLR regions 24 may be adjusted by the number of stacked layers of the partial FLRs configuring the p-type FLR regions 24. For example, a FLR 20a may be configured by p-type FLR regions 24a each having a 2-layer structure including the second and third regions 22, 23 that are upper layers (FIG. 3), a FLR 20b may be configured by p-type FLR regions 24b each having a single-layer structure including only the third regions 23 that are each an uppermost layer (FIG. 4). The p-type FLR regions 24 terminate at positions shallower from the front surface of the semiconductor substrate 10 than do the first and the second p⁺-type regions 61, 62 of the active region 1, whereby electric field may be concentrated in the active region 1 when excess load is applied.

For example, the second regions 22, in the depth direction Z, are center ones of the first to third regions 21 to 23 configuring the p-type FLR regions 24 and when the impurity concentration of the second regions 22 is lower than the impurity concentrations of the first and the third regions 21, 23 (refer to FIG. 2), in the edge termination region 2, there is less susceptibility to adverse effects of charge stored to a polyimide film (the first protective film 50) on the front surface of the semiconductor substrate 10. Therefore, pulling by the charge stored in the first protective film 50 and outward expansion, and inward contraction are suppressed, enabling stabilization of breakdown voltage characteristics of the FLR 20.

An adverse effect due to charge in the first protective film 50, for example, when the first protective film 50 is positively (plus) charged, is suppression of the spreading of a depletion layer in the n⁻-type drift region 32 in the edge termination region 2 by the positive charge in the first protective film 50. Further, when the first protective film 50 is negatively (minus) charged, the potential in the n⁻-type drift region 32 in the edge termination region 2 is pulled outward by the negative charge in the first protective film 50, facilitating spreading to near the n⁺-type stopper region 25.

As described above, the front surface of the semiconductor substrate 10 is free of a recess such as the recess 291 in the conventional structure (refer to FIG. 20) and therefore, the depth of the FLR 20 (depth of the p-type FLR regions 24) from the front surface of the semiconductor substrate 10 may be made deeper than the depth of the FLRs 220 (depths of the p⁻-type regions 221 and the p⁻⁻-type regions 222) from the second surface portion 210b of the front surface of the semiconductor substrate 210 having a conventional structure of a comparable breakdown voltage class. Therefore, compared to the conventional structure, a length (width in direction of normal) of the edge termination region 2 may be reduced.

Further, in the conventional structure, when the breakdown voltage is at least 10 kV, susceptibility to the effects of charge further increases, a field plate (FP) that is a floating metal electrode in contact with the FLR becomes necessary and therefore, the length of the edge termination region 202 further increases. On the other hand, in the first embodiment, the FLR 20 is configured by the p-type FLR regions 24, whereby even in an instance of a breakdown voltage of at least 10 kV, provision of a FP is unnecessary and therefore, the length of the edge termination region 2 may be shorter than that in the conventional structure and the voltage withstanding structure is stable with respect to charge.

In surface regions of the semiconductor substrate 10 at the front surface thereof, closer to the chip end than is the FLR 20, the n⁺-type stopper region 25 is selectively provided separate from the FLR 20. The n⁺-type stopper region 25 is formed in the second n⁻-type epitaxial layer 73 by ion implantation and is exposed at the front surface and the end of the semiconductor substrate 10. In the edge termination region 2, portions of the first and the second n⁻-type epitaxial layers 72, 73 excluding the p-type FLR regions 24 and the n⁺-type stopper region 25 are the n⁻-type drift region 32.

Between the p-type FLR regions 24 that are adjacent to one another, and between a most outer-peripheral one of the p-type FLR regions 24 and the n⁺-type stopper region 25, the n⁻-type drift region 32 formed by the first and the second n⁻-type epitaxial layers 72, 73 reaches and is exposed at the front surface of the semiconductor substrate 10. In this manner, on the n⁺-type starting substrate 71, only the n⁻-type epitaxial layers (the first and the second n⁻-type epitaxial layers 72, 73) are epitaxially grown, whereby the FLR 20 may be formed by ion implantation of a p-type impurity to the n⁻-type epitaxial layers alone.

As depicted in the other examples in FIGS. 5 and 6, the impurity concentration and the thickness of the p-type base region 34 of the active regions 1a, 1b may be variously adjusted and the impurity concentration and the thickness of the second regions 22 of the p-type FLR regions 24 may be adjusted. In this instance, configuration of the p-type FLR regions 24 in the depth direction Z in the edge termination region 2 is the same as the configuration of the portions of the p⁺⁺-type contact regions 36 in the depth direction Z in FIGS. 5 and 6. For example, in an instance of FIG. 5, in FIG. 2, the configuration of the second regions 22 is the same as the configuration of the p-type base region 34 of the portion of the second n⁻-type epitaxial layer 73a. Further, in an instance of FIG. 6, configuration is that in FIG. 2 without the second regions 22. The configuration of the intermediate region 3 may be the same as that of the intermediate region 3 in FIG. 2 or may be a configuration in which in FIG. 2, the configuration of the outer peripheral p-type base region 34c is the same as the configuration of the p-type base region 34 in FIGS. 5 and 6.

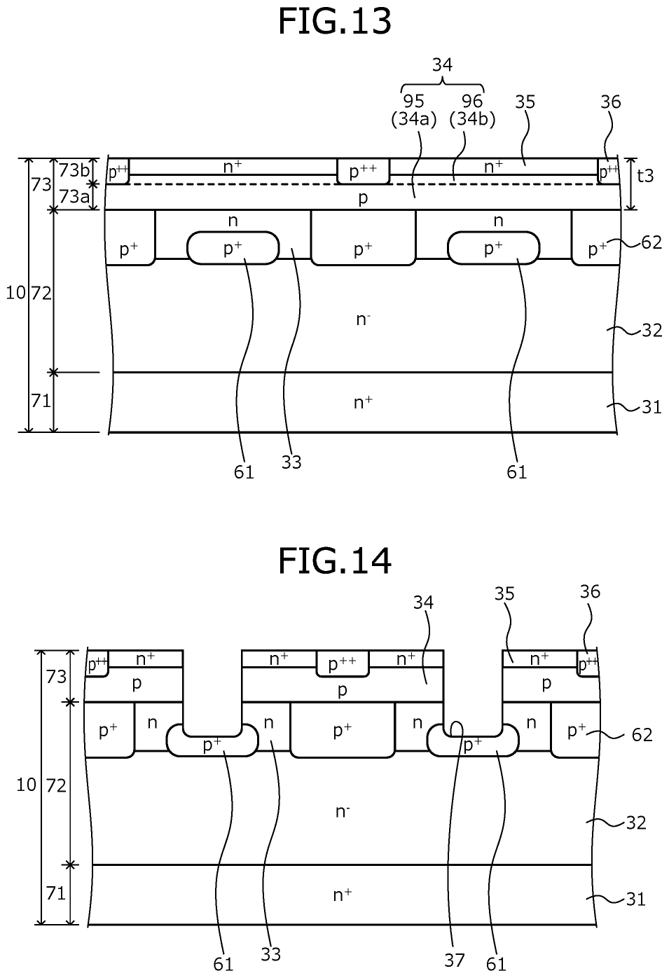

In forming the p-type base region 34 by ion implantation in the second n⁻-type epitaxial layer 73, for example, configuration may be such that the p-type base region 34 has a predetermined thickness penetrating through in the depth direction Z and the second n⁻-type epitaxial layer 73 is deposited in one stage (for example, refer to FIG. 6). Alternatively, configuration may be such that deposition of the second n⁻-type epitaxial layer 73 is divided into multiple stages, the second n⁻-type epitaxial layer 73 is deposited in stages (herein, 2 stages: reference characters 73a, 73b) until having a predetermined thickness t3, and p-type base regions 34a, 34b formed by ion implantation performed for each deposition of the second n⁻-type epitaxial layer 73 are connected in the depth direction Z, thereby forming the p-type base region 34 (refer to FIGS. 12 and 13).

In an instance in which the second n⁻-type epitaxial layer 73 (73a, 73b) is deposited in multiple stages, a p⁻-type base region 34d and the p-type base region 34b having differing p-type impurity concentrations may be respectively formed in the second n⁻-type epitaxial layers 73a, 73b and connected in the depth direction Z as the p-type base region 34 (FIG. 5). In this instance, gate threshold voltage may be suppressed by the p-type impurity concentration (for example, relatively reducing the p-type impurity concentration) of the p⁻-type base region 34d forming a portion of the p-type base region 34 facing the n⁻-type drift region 32.

In an instance in which the second n⁻-type epitaxial layer 73 is deposited in one stage, for example, deposition of the second n⁻-type epitaxial layer 73a is omitted, only the second n⁻-type epitaxial layer 73b is deposited (FIG. 6). In this instance, the thickness of the second n⁻-type epitaxial layer 73b is set so that the p-type base region 34 formed by ion implantation penetrates through in the depth direction Z. For example, the thickness of the second n⁻-type epitaxial layer 73b may be set to be equivalent to the depth of the p⁺⁺-type contact regions 36 and in the depth direction Z, the p⁺⁺-type contact regions 36 and the second p⁺-type regions 62 are caused to be in contact with one another.

A drain electrode (second electrode) 52 is in ohmic contact with an entire area of the back surface of the semiconductor substrate 10 (back surface of the n⁺-type starting substrate 71). On the drain electrode 52, a drain pad (electrode pad, not depicted) having a layered structure in which, for example, a Ti film, a nickel (Ni) film, and a gold (Au) film are sequentially stacked is provided. The drain pad is soldered to a metal base plate (not depicted) of an insulated substrate, the metal base plate being formed by, for example, copper (Cu) foil, and via the metal base plate, at least a portion is in contact with a base portion of a cooling fin (not depicted).

As described above, the terminal pins 49 are bonded to the Al electrode film 47 of the front surface of the semiconductor substrate 10, and the drain pad of the back surface is bonded to the metal base plate of the insulated substrate, whereby the semiconductor substrate 10 has a double-sided cooling structure having a cooling structure on each main surface. Heat generated by the semiconductor substrate 10 is dissipated from fin portions of the cooling fin, via the metal base plate bonded to the drain pad on the back surface of the semiconductor substrate 10 and from a metal bar to which the terminal pins 49 of the front surface of the semiconductor substrate 10 are bonded.

Operation of the semiconductor device 30 according to the first embodiment is described. In a state in which voltage (forward voltage) that is positive with respect to the source electrode (the Al electrode film 47) is applied to the drain electrode 52, when voltage at least equal to the gate threshold voltage is applied to the gate electrodes 39, a channel (n-type inversion layer) is formed in portions of the p-type base region 34 along the gate trenches 37. As a result, current that passes through the channel from the n⁺-type drain region 31 and to the n⁺-type source regions 35 flows, whereby the MOSFET (the semiconductor device 30) turns ON.

On the other hand, in a state in which forward voltage is applied between the source and drain, when voltage less than the gate threshold voltage is applied to the gate electrodes 39, in the active region 1, pn junctions between the first and the second p⁺-type regions 61, 62, the p-type base region 34, the n-type current spreading region 33, and the n⁻-type drift region 32 are reverse biased, whereby the MOSFET maintains the OFF state. At this time, a depletion layer spreads from the pn junctions, and electric field applied to the bottoms of the gate trenches 37 positioned closer to the source electrode than are the pn junctions is mitigated.

Furthermore, when the MOSFET is OFF, the depletion layer that spreads from the above-described pn junctions of the active region 1 spreads through the edge termination region 2 outwardly (toward the chip end) in the horizontal direction due to pn junctions between the p-type FLR regions 24, which are formed so as to surround the periphery of the active region 1, and the n⁻-type drift region 32. A predetermined breakdown voltage based on depletion layer width (width in a direction from the active region 1 to the chip end (direction of a normal of the p-type FLR regions 24 having a ring-shape)) and dielectric strength of silicon carbide may be secured to an extent that the depletion layer extends outwardly through the edge termination region 2.

Further, when the MOSFET is OFF, voltage that is negative with respect to the source electrode (the Al electrode film 47) is applied to the drain electrode 52, whereby current may be passed in a forward direction through a parasitic diode formed by pn junctions between the first and the second p⁺-type regions 61, 62, the p-type base region 34, the n-type current spreading region 33, and the n⁻-type drift region 32. For example, in an instance in which the MOSFET is device for an inverter, this parasitic diode built into the semiconductor substrate 10 may be used as a freewheeling diode for protecting the MOSFET itself.

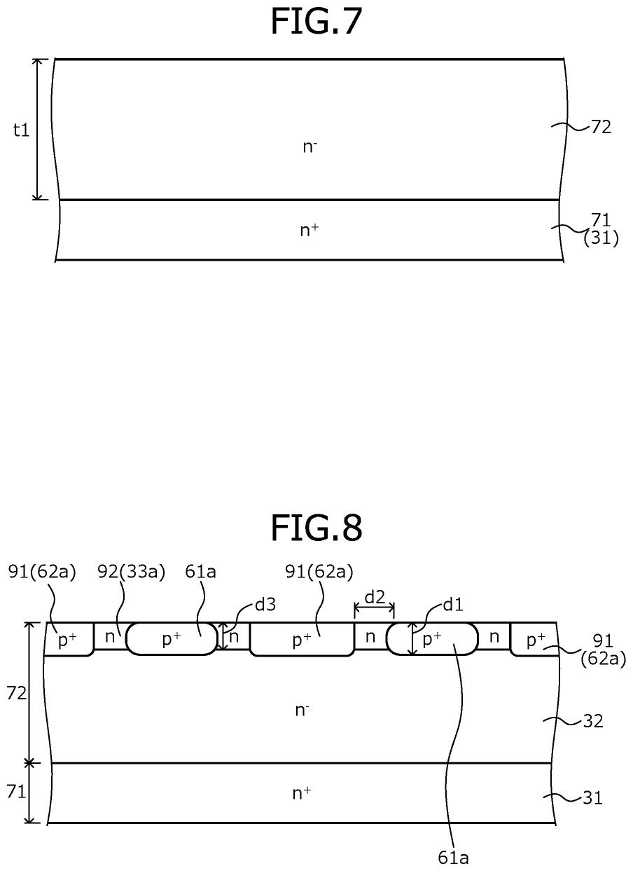

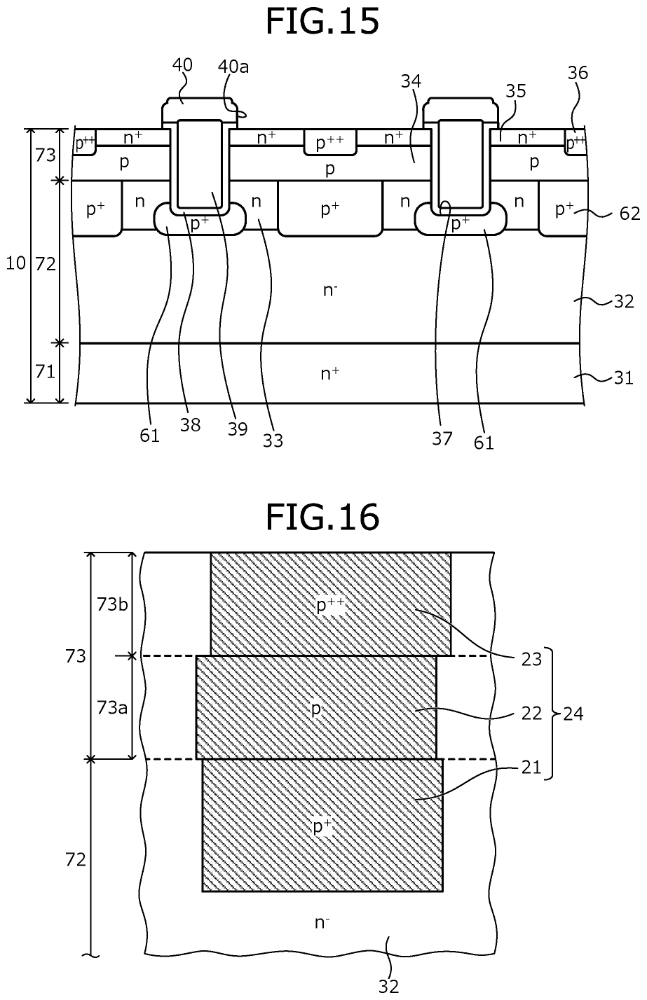

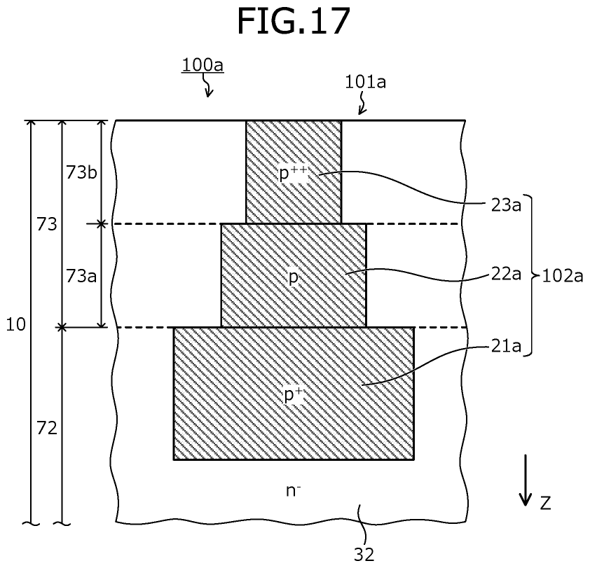

Next, a method of manufacturing the semiconductor device 30 according to the first embodiment is described. FIGS. 7, 8, 9, 10, 11, 12, 13, 14, 15, and 16 are cross-sectional views of states of the semiconductor device according to the first embodiment during manufacture. FIGS. 7 to 15 depict the active region 1 (refer to FIG. 2). In FIG. 16, while only one of the p-type FLR regions 24 configuring the FLR 20 (refer to FIG. 2) is depicted, as described above, the FLR 20 is configured by the multiple p-type FLR regions 24 each having the same configuration. Parts having the same impurity concentration and depth are formed concurrently in the edge termination region 2 and the intermediate region 3 in FIGS. 1 and 2, with parts having the same impurity concentration and depth formed in the active region 1.

First, as depicted in FIG. 7, as the n⁺-type starting substrate (semiconductor wafer) 71 containing silicon carbide, for example a silicon carbide single-crystal substrate doped with nitrogen is prepared. Next, on the front surface of the n⁺-type starting substrate 71, the first n⁻-type epitaxial layer 72 doped with nitrogen of a lower concentration than that of the n⁺-type starting substrate 71 is epitaxially grown. A thickness t1 of the first n⁻-type epitaxial layer 72, in an instance of a breakdown voltage of 3300V, for example, is about 30 μm and in an instance of a breakdown voltage of 1200V, for example, is about 10 μm.

Next, as depicted in FIG. 8, in the active region 1, the first p⁺-type regions 61 and p⁺-type regions 91 that are portions of the second p⁺-type regions 62 are formed in surface regions of the first n⁻-type epitaxial layer 72 by photolithography and ion implantation of a p-type impurity such as, for example, Al. At this time, the p⁺-type regions 91 that are a portion of the outer peripheral p⁺-type region 62a in the intermediate region 3 and portions (the first regions 21) of the multiple p-type FLR regions 24 configuring the FLR 20 in the edge termination region 2 are formed in surface regions of the first n⁻-type epitaxial layer 72, concurrently with the first p⁺-type regions 61.

Next, in the active region 1, n-type regions 92 that are portions of the n-type current spreading region 33 are formed in surface regions of the first n⁻-type epitaxial layer 72 by photolithography and ion implantation of an n-type impurity such as, for example, nitrogen. At this time, concurrently with the n-type regions 92 that are portions of the n-type current spreading region 33, the n-type regions 92 that are portions of the outer-peripheral n-type current spreading region 33a are formed in surface regions of the first n⁻-type epitaxial layer 72 in the intermediate region 3 and the edge termination region 2. A sequence in which the n-type regions 92 and the p⁺-type regions 61, 91 are formed may be interchanged.

In the edge termination region 2, the n-type regions 92 that are portions of the outer-peripheral n-type current spreading region 33a are formed between the first regions 21 that are adjacent to one another. In the active region 1, a distance d2 between the p⁺-type regions 61, 91 that are adjacent to one another is, for example, about 1.5 μm. The p⁺-type regions 61, 91, for example, have a depth d1 that is about 0.5 μm and an impurity concentration that is in a range from about 3.0×10¹⁸/cm³ to 7.0×10¹⁸/cm³. The n-type regions 92, for example, have a depth d3 that is about 0.4 μm and an impurity concentration that is in a range from about 5.0×10¹⁶/cm³ to 1.0×10¹⁷/cm³.

In the first n⁻-type epitaxial layer 72, portions of free of implanted ions are the n⁻-type drift region 32. In the edge termination region 2, between an outer (relatively closest to the chip end) end of the n-type regions 92 that are portions of the outer-peripheral n-type current spreading region 33a and an end of a chip region (region that becomes the semiconductor chip after dicing of the semiconductor wafer), the n⁻-type drift region 32 (portions of the first n⁻-type epitaxial layer 72 free of implanted ions) is left and exposed at the surface of the first n⁻-type epitaxial layer 72.

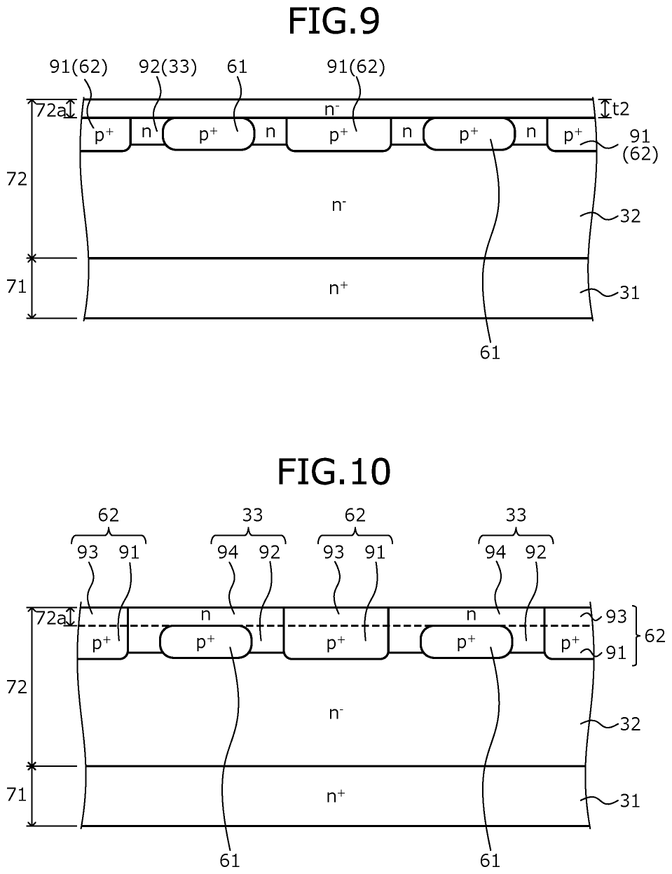

Next, as depicted in FIG. 9, an n⁻-type epitaxial layer doped with an n-type impurity such as, for example, nitrogen is further epitaxially grown on the first n⁻-type epitaxial layer 72 and has a thickness t2 of, for example, about 0.5 μm, whereby the first n⁻-type epitaxial layer 72 has a predetermined thickness. An impurity concentration of a portion 72a that increases the thickness of the first n⁻-type epitaxial layer 72 may be, for example, 3×10¹⁵/cm³. In the edge termination region 2, a portion of the n⁻-type drift region 32 opposing the portion 72a in the depth direction Z is connected to the portion 72a that increases the thickness of the first n⁻-type epitaxial layer 72.

Next, as depicted in FIG. 10, by photolithography and ion implantation of a p-type impurity such as Al, in the active region 1, p⁺-type regions 93 that are portions of the second p⁺-type regions 62 are formed in the portion 72a that increases the thickness of the first n⁻-type epitaxial layer 72. At this time, concurrently with the p⁺-type regions 93, the p⁺-type regions 93 that are portions of the outer peripheral p⁺-type region 62a of the intermediate region 3 and portions (the first regions 21) of the multiple p-type FLR regions 24 configuring the FLR 20 of the edge termination region 2 are formed in the portion 72a that increases the thickness of the first n⁻-type epitaxial layer 72.

Next, by photolithography and ion implantation of an n-type impurity such as, for example, nitrogen, in the active region 1, n-type regions 94 that are portions of the n-type current spreading region 33 are formed in the portion 72a that increases the thickness of the first n⁻-type epitaxial layer 72. At this time, in the intermediate region 3 and the edge termination region 2, concurrently with the n-type regions 94 that are portions of the n-type current spreading region 33, the n-type regions 94 that are portions of the outer-peripheral n-type current spreading region 33a are formed in the portion 72a that increases the thickness of the first n⁻-type epitaxial layer 72.

In the portion 72a that increases the thickness of the first n⁻-type epitaxial layer 72, portions thereof free of implanted ions are the n⁻-type drift region 32. In the edge termination region 2, between an outer (relatively closest to the chip end) end of the n-type regions 94 that are portions of the outer-peripheral n-type current spreading region 33a and the end of the chip region, the n⁻-type drift region 32 (in the portion 72a that increases the thickness of the first n⁻-type epitaxial layer 72, portions thereof free of implanted ions) is left and exposed at the surface of the portion 72a that increases the thickness of the first n⁻-type epitaxial layer 72.

The p⁺-type regions 91, 93 that are adjacent to one another in the depth direction Z are connected to one another, whereby the second p⁺-type regions 62, the outer peripheral p⁺-type region 62a, and the first regions 21 of the multiple p-type FLR regions 24 are formed. The n-type regions 92, 94 that are adjacent to one another in the depth direction Z are connected, whereby the n-type current spreading region 33 and the outer-peripheral n-type current spreading region 33a are formed. Conditions such as the impurity concentrations of the p⁺-type regions 93 and the n-type regions 94, for example, are the same as those of the p⁺-type regions 91 and the n-type regions 92. A sequence in which the p⁺-type regions 93 and the n-type regions 94 are formed may be interchanged.

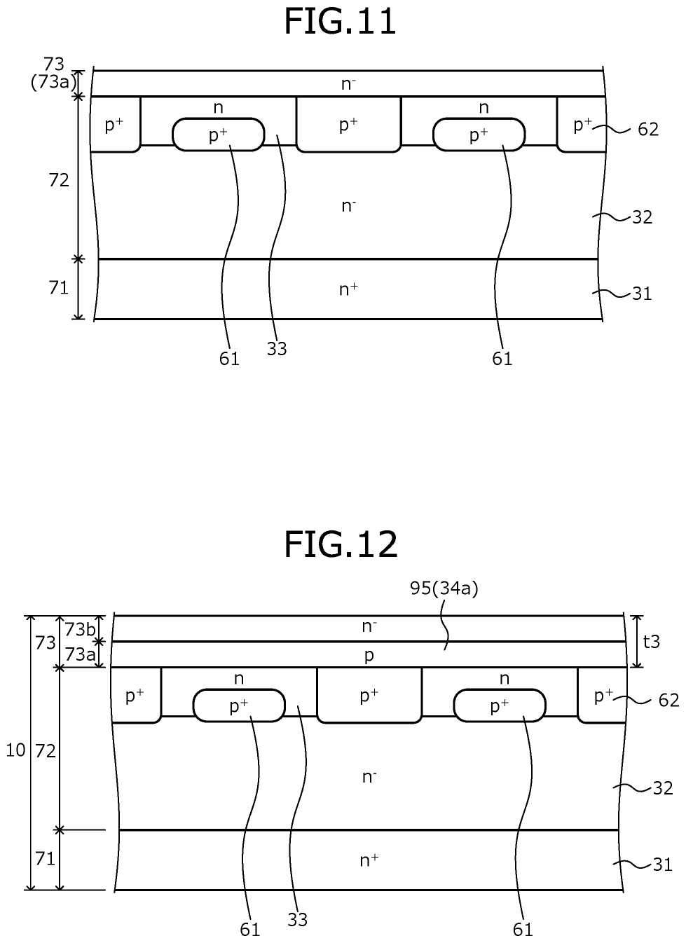

Next, as depicted in FIG. 11, the second n⁻-type epitaxial layer 73 (73a) doped with an n-type impurity such as, for example, nitrogen is epitaxially grown on the first n⁻-type epitaxial layer 72. Next, as depicted in FIG. 12, in the active region 1, by photolithography and ion implantation of a p-type impurity such as Al, p-type regions 95 that are portions (the p-type base region 34a) of the p-type base region 34 are formed in the second n⁻-type epitaxial layer 73a so as to penetrate through the second n⁻-type epitaxial layer 73a in the depth direction Z. The p-type regions 95 have an impurity concentration in a range, for example, from about 1.0×10¹⁷/cm³ to 8.0×10¹⁸/cm³.

At this time, concurrently with the p-type regions 95 that are the p-type base region 34a, the p-type regions 95 that are a portion of the outer peripheral p-type base region 34c in the intermediate region 3 and portions (the second regions 22) of the multiple p-type FLR regions 24 configuring the FLR 20 in the edge termination region 2 are formed in the second n⁻-type epitaxial layer 73 (73a). Next, the second n⁻-type epitaxial layer 73b doped with an n-type impurity such as, for example, nitrogen is further epitaxially grown on the second n⁻-type epitaxial layer 73a, whereby the second n⁻-type epitaxial layer 73 (73a, 73b) has the predetermined thickness t3.

Next, in the active region 1, a p-type region 96 that is a portion of the p-type base region 34 (the p-type base region 34b) is formed in the second n⁻-type epitaxial layer 73 (73b) by photolithography and ion implantation of a p-type impurity such as Al. At this time, concurrently with the p-type region 96 that is the p-type base region 34b, the p-type regions 96 that are a portion of the outer peripheral p-type base region 34c in the intermediate region 3 and portions (the second regions 22) of the multiple p-type FLR regions 24 configuring the FLR 20 in the edge termination region 2 are formed in the second n⁻-type epitaxial layer 73b.

The second n⁻-type epitaxial layers 73a, 73b each have an impurity concentration that is, for example, about 4.0×10¹⁷/cm³. The second n⁻-type epitaxial layers 73a, 73b are stacked, thereby forming the second n⁻-type epitaxial layer 73 of the predetermined thickness t3. The thickness t3 of the second n⁻-type epitaxial layer 73 is, for example, about 1.1 μm. The p-type regions 95, 96 that are adjacent to one another in the depth direction Z are connected, whereby the p-type base region 34, the outer peripheral p-type base region 34c, and the second regions 22 of the multiple p-type FLR regions 24 are formed.

Respective thicknesses of the second n⁻-type epitaxial layers 73a, 73b are such that the p-type regions 95, 96 formed by ion implantation in the second n⁻-type epitaxial layers 73a, 73b, respectively, penetrate therethrough in the depth direction Z. In an instance in which the predetermined thickness t3 of the second n⁻-type epitaxial layer 73 is a thickness allowing the p-type base region 34 formed by ion implantation to penetrate therethrough, the second n⁻-type epitaxial layer 73 may be deposited to have the predetermined thickness t3 by one stage without dividing the deposition (epitaxial growth) into two stages for the second n⁻-type epitaxial layers 73a, 73b.

A reason for this is as follows. In the conventional structure (refer to FIG. 20), at the point when the p-type epitaxial layer 273 that forms the p-type base regions 234 is epitaxially growth, the p-type base regions 234 and the second p⁺-type regions 262 formed in the n⁻-type epitaxial layer 272 by ion implantation are in contact with one another in the depth direction Z. On the other hand, in the first embodiment, for example, the thickness t3 of the second n⁻-type epitaxial layer 73 deposited in one stage, or respective thicknesses of the second n⁻-type epitaxial layers 73a, 73b deposited separately in two stages are assumed to be too thick.

In this instance, the p-type base region 34, the outer peripheral p-type base region 34c, and the second regions 22 of the multiple p-type FLR regions 24 formed in the second n⁻-type epitaxial layer 73 deposited in one stage by ion implantation are not at depths penetrating through the second n⁻-type epitaxial layer 73. Alternatively, the p-type regions 95, 96 formed by ion implantation in the second n⁻-type epitaxial layers 73a, 73b deposited in two stages are not at depths penetrating through the second n⁻-type epitaxial layers 73a, 73b.

The p-type base region 34 and the second p⁺-type regions 62 are disconnected by n⁻-type regions (the n⁻-type drift region 32) left between the p-type base region 34 and the second p⁺-type regions 62 in the first n⁻-type epitaxial layer 72. Therefore, in an instance in which the second n⁻-type epitaxial layer 73 is deposited in one stage, the thickness t3 suffices to be thin enough allowing the p-type base region 34 formed by ion implantation to penetrate through the second n⁻-type epitaxial layer 73 and preferably, may be in a range from at least a thickness necessary for a channel (n-type inversion layer) (for example, about 0.5 μm) to about 0.8 μm.

Therefore, the thickness t3 of the second n⁻-type epitaxial layer 73 deposited in one stage, or the respective thicknesses of the second n⁻-type epitaxial layers 73a, 73b deposited in two stages, for example, are thinner as compared to the thickness t201 of the p-type epitaxial layer 273 that forms the p-type base regions 234 of the conventional structure (refer to FIG. 20). By the processes up to here, the semiconductor substrate 10 (semiconductor wafer) of an n-type and in which only the n⁻-type epitaxial layers (the first and the second n⁻-type epitaxial layers 72, 73) are sequentially stacked on the n⁺-type starting substrate 71 is fabricated.

In the edge termination region 2, the n⁻-type drift region 32, at a portion thereof facing the second n⁻-type epitaxial layer 73 in the depth direction Z, is connected to the second n⁻-type epitaxial layer 73. Portions of the second n⁻-type epitaxial layer 73 free of implanted ions are the n⁻-type drift region 32. In the edge termination region 2, portions of the n⁻-type drift region 32 left: between the outer peripheral p-type base region 34c and a most inner-peripheral one of the second regions 22, between the second regions 22 adjacent to one another, and between a most outer-peripheral one of the second regions 22 and the chip end, are exposed at the surface of the second n⁻-type epitaxial layer 73.

Next, as depicted in FIG. 13, a process including photolithography and ion implantation as one set is repeatedly performed under differing conditions. As a result, in the active region 1, the n⁺-type source regions 35 and the p⁺⁺-type contact regions 36 are formed in surface regions of the second n⁻-type epitaxial layer 73. In the edge termination region 2, the n⁺-type stopper region 25 is formed in surface regions of the second n⁻-type epitaxial layer 73. A sequence in which the n⁺-type source regions 35, the p⁺⁺-type contact regions 36, and the n⁺-type stopper region 25 are formed may be interchanged.

At this time, in surface regions of the second n⁻-type epitaxial layer 73, concurrently with the p⁺⁺-type contact regions 36, p⁺-type regions (not depicted) that are the outer peripheral p⁺⁺-type contact region 36a in the intermediate region 3 and the third regions 23 of the multiple p-type FLR regions 24 configuring the FLR 20 in the edge termination region 2 are formed. An impurity concentration of the third regions 23 is, for example, in a range from about 1.0×10¹⁷/cm³ to 5.0×10²⁰/cm³. As described above, the first to the third regions 21 to 23 adjacent to one another in the depth direction Z and formed in the first and the second n⁻-type epitaxial layers 72 (72a), 73 (73a, 73b), respectively, are all connected, thereby forming the p-type FLR regions 24.

Misalignment of about 0.1 μm in the direction of a normal (the horizontal direction in FIG. 16) inevitably occurs among the first to the third regions 21 to 23 adjacent to one another in the depth direction Z, due to the positioning (alignment) accuracy of an ion implantation mask used in forming the first to the third regions 21 to 23. As a result, the interval between the p-type FLR regions 24 that are adjacent to one another may be substantially reduced. A magnitude of the misalignment between the first to the third regions 21 to 23 that are adjacent to one another in the depth direction Z is, for example, in a range from about 0.05 μm to 0.3 μm. Widths of the first to the third regions 21 to 23 (width in the direction of a normal of the p-type FLR regions 24 having a ring-shape) are substantially the same. Substantially the same width means a same width within a range that includes an allowed error due to process variation.

In FIG. 16, misalignment, in the direction of a normal, between the first regions 21 formed in two stages (between the p⁺-type regions 91, 93) is not depicted, this misalignment being due to ion implantation to the portion of the first n⁻-type epitaxial layer 72 first deposited (refer to FIG. 8) and ion implantation to the portion 72a that increases the thickness of the first n⁻-type epitaxial layer 72 (refer to FIG. 9). Misalignment, in the direction of a normal, between the second regions 22 (between the p-type regions 95, 96) formed in two stages in the second n⁻-type epitaxial layers 73a, 73b (refer to FIGS. 12 and 13), respectively, is not depicted, this misalignment being due to the ion implantations to the second n⁻-type epitaxial layers 73a, 73b.

When misalignment in the direction of a normal occurs between the partial FLRs (the first to the third regions 21 to 23) that are adjacent to one another in the depth direction Z, electric field increases locally where the misalignment occurs. Therefore, for example, in an instance in which the FLR 20 of the first embodiment is applied to a semiconductor device using silicon as a semiconductor material, avalanche breakdown occurs due to the pn junctions between the partial FLRs where misalignment in the direction of a normal occurs and the n⁻-type drift region, and destruction easily occurs due to electric current (hereinafter, avalanche current) flowing toward the source electrode, from places where the avalanche breakdown occurs.

One cause of destruction due to avalanche current is because parasitic operation easily occurs due to built-in voltage of a silicon pn junction face being small at 0.6V. In an instance in which the semiconductor device using silicon as a semiconductor material is a MOSFET, avalanche current flows as forward current of a parasitic diode of the MOSFET and destruction easily occurs due to degradation occurring over time due to parasitic diode operations. In an instance in which the semiconductor device that uses silicon as a semiconductor material is an IGBT, destruction easily occurs due to a parasitic thyristor of the IGBT being turned ON by the avalanche current.

Further, in an instance in which the FLR 20 of the first embodiment is applied to the semiconductor device in which silicon is used as a semiconductor material, during operation under a high temperature (for example, at least 200 degrees C.), adverse effects due to leak current are large at places where misalignment in the direction of a normal occurs between the partial FLRs that are adjacent to one another in the depth direction Z, and destruction occurs more easily. In particular, the leak current increases to at least 10 mA under high-temperature operation of 200 degrees C., leading to immediate destruction. On the other hand, as described above, silicon carbide has a bandgap that is wider than a bandgap of silicon and therefore, in a semiconductor device in which silicon carbide is used as a semiconductor material, leak current is small even during high temperature operation.

In the first embodiment, even when there are places where electric field is locally high due to misalignment, in the direction of a normal, between the partial FLRs that are adjacent to one another in the depth direction Z, the bandgap of silicon carbide is wide and therefore, the leak current does not increase. In addition to this, the built-in voltage of a silicon carbide pn junction face is high, being in a range from about 3V to 5V and therefore, parasitic operation does not easily occur, whereby destruction does not easily occur. Therefore, it suffices to set the number of stacked layers and the impurity concentration of the partial FLRs configuring the p-type FLR regions 24 with consideration of misalignment, in the direction of a normal, between the partial FLRs that are adjacent to one another in the depth direction Z.

For example, by increasing the number of stacked layers of the partial FLRs configuring the p-type FLR regions 24, the p-type FLR regions 24 becomes deeper and therefore, there is less susceptibility to adverse effects of charge, and even when misalignment, in the direction of a normal, occurs between the partial FLRs that are adjacent to one another in the depth direction Z, destruction does not easily occur. Further, there is less susceptibility to adverse effects of charge and therefore, in the edge termination region 2, the thickness of the first protective film 50 may be thin at about 5 μm (a thickness of the protective film 250 of the edge termination region 202 of the conventional structure is about 10 μm), and a nitride film (SiN film) may be provided instead of the first protective film 50.

The partial FLRs configuring the p-type FLR regions 24 may have an impurity concentration that is, for example, at least about 1×10¹⁶/cm³; the partial FLRs may be formed concurrently with any of the p-type regions of the MOSFET of the active region 1 and may have substantially the same impurity concentration as that of the p-type regions or may be set for the FLR 20. Impurity concentrations of the partial FLRs configuring the p-type FLR regions 24 may all be substantially the same or may be respectively different. Substantially the same impurity concentration means a same impurity concentration within a range that includes an allowed error due to process variation.

For example, as described above, in an instance in which the first to the third regions 21 to 23 of the p-type FLR regions 24 are respectively formed concurrently with the second p⁺-type regions 62, the p-type base region 34, and the p⁺⁺-type contact regions 36, impurity concentrations of the first to the third regions 21 to 23 are, for example, about 5×10¹⁸/cm³, about 4×10¹⁷/cm³, and about 3×10²⁰/cm³, respectively. Thicknesses of the first to the third regions 21 to 23 may be substantially the same. Substantially the same thickness means a same thickness within a range that includes an allowed error due to process variation.

The partial FLRs may be formed by respective ion implantations in the multiple n⁻-type epitaxial layers having thin thicknesses and deposited in multiple stages, and the number of stacked layers of the partial FLRs configuring the p-type FLR regions 24 may be increased. The thinner are the thicknesses of the n⁻-type epitaxial layers configuring the partial FLRs, the more uniform (BOX profile), in the depth direction Z, the p-type impurity concentration of the partial FLRs formed in the n⁻-type epitaxial layers by ion implantation may be. The impurity concentration being uniform means substantially a same impurity concentration within a range that includes an allowed error due process variation.

Next, impurity activation is performed for all diffused regions formed by ion implantation (the first and the second p⁺-type regions 61, 62, the n-type current spreading region 33, the p-type base region 34, the n⁺-type source regions 35, the p⁺⁺-type contact regions 36, the outer-peripheral n-type current spreading region 33a, the outer peripheral p-type base region 34c, the outer peripheral p⁺⁺-type contact region 36a, the p-type FLR regions 24, and the n⁺-type stopper region 25), for example, by a heat treatment of a temperature of about 1700 degrees C. for about 2 minutes. Impurity activation for all of the diffused regions may be performed collectively by a single session of the heat treatment or the heat treatment may be performed for each ion implantation.

Next, as depicted in FIG. 14, the gate trenches 37 that penetrate through the n⁺-type source regions 35, the p-type base region 34, and the n-type current spreading region 33 from the front surface of the semiconductor substrate 10 and reach the first p⁺-type regions 61 are formed by photolithography and etching. Next, as depicted in FIG. 15, the gate insulating films 38 are formed along the front surface of the semiconductor substrate 10 (respective surfaces of the n⁺-type source regions 35, the p⁺⁺-type contact regions 36, and the outer peripheral p⁺⁺-type contact region 36a) and inner walls (sidewalls and bottoms) of the gate trenches 37.

The gate insulating films 38 may be, for example, a thermal oxide film formed by thermal oxidation of the semiconductor surface by a temperature of about 1000 degrees C. under an oxygen (O₂) atmosphere or may be a deposited film formed by a high temperature oxide (HTO). Next, a polysilicon layer doped with, for example, phosphorus (P) is deposited (formed) on the front surface of the semiconductor substrate 10 so as to be embedded in the gate trenches 37 and is selectively removed, leaving only portions thereof forming the gate electrodes 39 in the gate trenches 37.

Further, concurrently when the portions of the polysilicon layer are left as the gate electrodes 39, a portion of the polysilicon layer may be left as the gate polysilicon wiring layer 82. In this instance, after the formation of the gate insulating films 38 but before deposition of the polysilicon layer doped with phosphorus, the field oxide film 81 is formed on the front surface of the semiconductor substrate 10 in the intermediate region 3 and the edge termination region 2. While not depicted in FIG. 2, the gate insulating films 38 may be left between the front surface of the semiconductor substrate 10 and the field oxide film 81.

Next, the interlayer insulating film 40 containing, for example, borophosphosilicate glass (BPSG), PSG, etc. and covering an entire area of the front surface of the semiconductor substrate 10, the gate electrodes 39, and the gate polysilicon wiring layer 82, for example, is formed having a thickness of 1 μm. Next, in the active region 1, the contact holes 40a, 40b penetrating through the interlayer insulating film 40 and the gate insulating films 38 in the depth direction Z are formed by photolithography and etching. In the intermediate region 3, the contact hole 40c that penetrates the interlayer insulating film 40 in the depth direction Z is formed.

In the contact holes 40a, the n⁺-type source regions 35 and the p⁺⁺-type contact regions 36 in the active region 1 are exposed. In the contact hole 40b, the outer peripheral p⁺⁺-type contact region 36a is exposed. In the contact hole 40c, the gate polysilicon wiring layer 82 is exposed. Next, the interlayer insulating film 40 is planarized (reflow) by a heat treatment. Next, the first TiN film 42 covering the interlayer insulating film 40 only in the active region 1 is formed. Next, the NiSi films 41 are formed on portions of the front surface of the semiconductor substrate 10 exposed in the contact holes 40a. Further, a NiSi film is formed as the drain electrode 52 in ohmic contact with the back surface of the semiconductor substrate 10.

Next, the first Ti film 43, the second TiN film 44, and the second Ti film 45 are sequentially stacked so as to cover the NiSi films 41 and the first TiN film 42, whereby the barrier metal 46 is formed so as to cover substantially an entire area of the active region 1. Next, the Al electrode film 47 is deposited on the second Ti film 45. Concurrently with the Al electrode film 47, a gate pad (not depicted) is formed on the interlayer insulating film 40, separate from the Al electrode film 47 and in the contact hole 40c, the gate metal wiring layer 83 is formed on the gate polysilicon wiring layer 82.

Next, on a surface of the drain electrode 52, for example, a Ti film, a Ni film, and a gold (Au) film are sequentially stacked, thereby forming the drain pad (not depicted). Next, the first protective film 50 containing a polyimide is formed in an entire area of the front surface of the semiconductor substrate 10; and the Al electrode film 47, the gate pad, and the gate metal wiring layer 83 are covered by the first protective film 50.

Next, the first protective film 50 is selectively removed, the Al electrode film 47 and the gate pad are exposed, respectively, by different openings of the first protective film 50. Next, after a general plating pretreatment process, the plating films 48 are formed by a general plating process, in portions (the source pad) of the Al electrode film 47 exposed in the openings of the first protective film 50. Next, the plating films 48 are dried by a heat treatment (baking). Next, the second protective films 51 containing a polyimide are formed, covering borders between the plating films 48 and the first protective film 50.

Next, the strength of the polyimide films (the first and the second protective films 50, 51) is enhanced by a heat treatment (curing). Next, the terminal pins 49 are bonded on the plating films 48 by solder layers, respectively. On the gate pad as well, concurrently with the wiring structure on the Al electrode film 47, a first protective film, a plating film, and a second protective film are sequentially formed, whereby the wiring structure to which the terminal pins are bonded by the solder layer is formed. Thereafter, the semiconductor substrate 10 (semiconductor wafer) is diced (cut) into individual chips, whereby the MOSFET (the semiconductor device 30) depicted in FIGS. 1 and 2 is completed.

As described above, according to the first embodiment, the semiconductor substrate is fabricated by stacking only the n⁻-type epitaxial layers, whereby a main part (portion near a channel) of the MOSFET in the active region is configured by the n⁻-type epitaxial layers. As a result of this, crystallinity is favorable and a channel having a low impurity concentration may be formed, whereby junction FET (JFET) resistance between the first and the second p⁺-type regions that mitigate electric field applied to bottoms of gate trenches is reduced and conduction loss may be reduced.

Further, according to the first embodiment, the semiconductor substrate is fabricated by stacking only the n⁻-type epitaxial layers, whereby the FLR may be formed by disposing, in a concentric shape surrounding the periphery of the active region, the p-type FLR regions formed by ion implantation in the n⁻-type epitaxial layers that are deposited in multiple stages. Therefore, in an edge termination region such as that of the conventional structure (refer to FIG. 20), the recess for exposing the n⁻-type epitaxial layers need not be formed at the front surface of semiconductor substrate and an entire area of the front surface of the semiconductor substrate is a flat face, continuous from the active region to the chip end.

Further, in the conventional structure, in an instance in which the FLRs 220 are a spatial modulator type, as described above, overlapping ion implantations for forming the p⁻-type regions 221 and the p⁻⁻-type regions 222 that configure the FLRs 220 is complicated and positioning of the ion implantation masks is difficult. On the other hand, according to the first embodiment, the partial FLRs of differing impurity concentrations are formed for each deposition stage of the n⁻-type epitaxial layers, the partial FLRs are adjacent to one another in the depth direction, forming the p-type FLR regions, whereby the impurity concentration distribution of the p-type FLR regions in the depth direction may be easily adjusted.

Further, according to the first embodiment, increasing the number of stacked layers of the partial FLRs configuring the p-type FLR regions is easy, and by increasing the number of stacked layers of the partial FLRs configuring the p-type FLR regions, the depth of the p-type FLR regions from the front surface of the semiconductor substrate may be easily adjusted. For example, the deeper the depth of the p-type FLR regions from the front surface of the semiconductor substrate is increased by increasing the number of stacked partial FLRs configuring the p-type FLR regions, the narrower a length (width in direction of normal) of the edge termination region may be in a state in which the breakdown voltage is sustained.

On the other hand, by reducing the number of stacked layers of the partial FLRs configuring the p-type FLR regions, in the active region, the p-type FLR regions are terminated at positions shallower from the front surface of the semiconductor substrate than are the first and the second p⁺-type regions that mitigate electric field applied to the bottoms of the gate trenches, whereby electric field may be concentrated in the active region when excess load is applied to a semiconductor device element. As a result, a reverse bias safe operating area (RBSOA) of the semiconductor device element may be secured.

In this manner, according to the first embodiment, the impurity concentration and depth of the p-type FLR regions may be easily adjusted and a voltage withstanding structure (FLR) with a high degree of completeness may be easily formed. The degree of completeness of the voltage withstanding structure is high, whereby the reliability of the semiconductor device may be enhanced. Further, like the conventional structure, an etching process for forming a recess at the front surface of the semiconductor substrate and discarded material (portions of the p-type epitaxial layer forming the p-type base regions) due to the etching do not occur, whereby an economical and stable voltage withstanding structure may be assured.

Next, a structure of a semiconductor device according to a second embodiment is described. FIGS. 17, 18, and 19 are cross-sectional views of examples of the voltage withstanding structure of the semiconductor device according to the second embodiment. In FIGS. 17 to 19, while one each of p-type FLR regions 102a, 102b, 102c configuring FLRs 101a, 101b, 101c in the edge termination region of semiconductor devices 100a, 100b, and 100c according to the second embodiment is depicted, the FLRs 101a to 101c of the second embodiment as well, similarly to the FLR 20 (refer to FIG. 2) of the first embodiment, are configured by the multiple p-type FLR regions 102a to 102c having a same configuration surrounding a periphery of the active region in a concentric shape.

The semiconductor devices 100a to 100c according to the second embodiment depicted in FIGS. 17 to 19 differ from the semiconductor device 30 according to the first embodiment (FIGS. 2, 16) in that a width (width in direction of normal) of at least one of the plural partial FLRs (p-type regions) configuring the p-type FLR regions adjacent to one another in the depth direction Z is relatively wide. For example, the p-type FLR regions 102a may each have a 3-layer structure in which first, second, third regions (partial FLRs) 21a, 22a, 23a are disposed adjacent to one another in ascending order of width in the depth direction Z from the front surface of the semiconductor substrate 10 and the p-type FLR regions 102a may be disposed in plural, in a concentric shape surrounding the periphery of the active region, thereby forming a FLR 101a (FIG. 17).

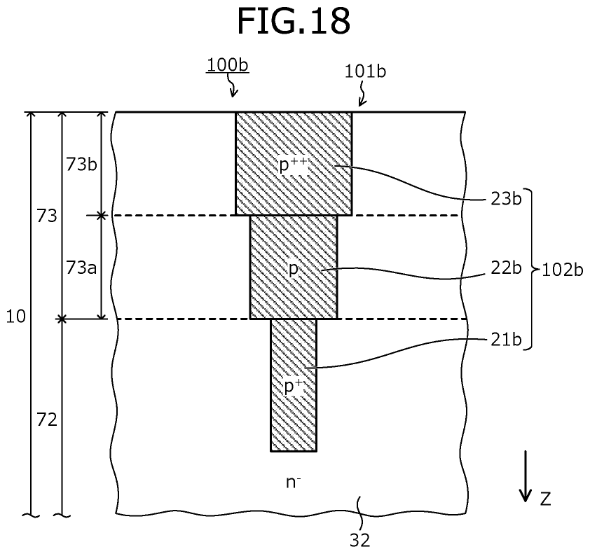

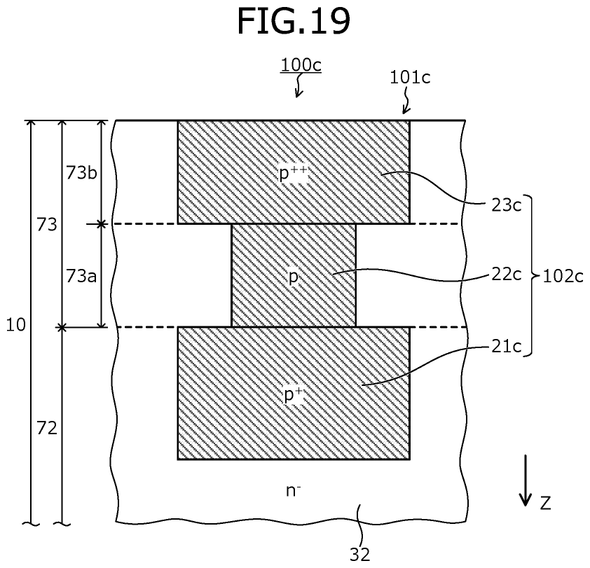

Further, the p-type FLR regions 102b may have a 3-layer structure in which first, second, third regions (partial FLRs) 21b, 22b, 23b are disposed adjacent to one another in descending order of width in the depth direction Z from the front surface of the semiconductor substrate 10 and the p-type FLR regions 102b may be disposed in plural, in a concentric shape surrounding the periphery of the active region, thereby forming a FLR 101b (FIG. 18). The p-type FLR regions 102c may have a 3-layer structure in which first and third regions (partial FLRs) 21c, 23c each having a width that is wider the shallower or deeper from the front surface of the semiconductor substrate 10 in the depth direction Z the first and the third regions 21c, 23c are respectively disposed as compared to center second regions (partial FLRs) 22c adjacent thereto, and the p-type FLR regions 102c may be disposed in plural, in a concentric shape surrounding the periphery of the active region, thereby forming a FLR 101c (FIG. 19).

Adjustment of the impurity concentration of the p-type FLR regions 102a to 102c is further facilitated by variously changing the widths of the partial FLRs. In the FLRs 101a to 101c of the second embodiment described above, in an in-plane direction of the semiconductor substrate 10 from the active region 1 to the edge termination region 2, a widest one of the partial FLRs is configured having both ends thereof protruding more than those of the other partial FLRs. In this instance, the widest one of the partial FLRs determines an interval between the p-type FLR regions 102a to 102c that are adjacent to one another and therefore, even when alignment of the layers of the partial FLRs is shifted, stable and high breakdown voltage may be obtained.

Regarding positions in the direction of a normal (the horizontal direction in FIGS. 17 to 19) between the partial FLRs that are adjacent to one another in the depth direction Z, the widest one of the partial FLRs may be formed so as to protrude beyond the other partial FLRs by at least 0.05 μm inwardly and outwardly in the direction of the normal. A difference of the positions in the direction of the normal between the partial FLRs that are adjacent to one another in the depth direction Z is variously changed depending on a necessary breakdown voltage. Further, similarly to FIG. 19, in an instance in which more than one of the partial FLRs has a widest width, in the first and the third regions (partial FLRs) 21c, 23c, effects similar to those of the first embodiment are obtained and in the second regions (partial FLRs) 22c, effects shown in the second embodiment are obtained.

As described above, according to the second embodiment, the width of at least one partial FLR of the multiple partial FLRs that are adjacent in the depth direction and configure one of the p-type FLR regions is relatively wide. As a result, even when at least one of the multiple partial FLRs that are adjacent in the depth direction and configure one of the p-type FLR regions is formed shifted from a predetermined position in the direction of a normal of the p-type FLR regions, all of the partial FLRs may be in contact with one another in the depth direction by the one or more partial FLRs having a relatively wide width. As a result, the degree of completeness of the FLR is further increased, whereby effects similar to those of the first embodiment may be obtained.

In the foregoing, without limitation to the described embodiments, in the invention, various modifications are possible within a range not departing from the spirit of the invention. For example, the present invention is applicable even in an instance in which, instead of using silicon carbide as a semiconductor material, a wide bandgap semiconductor other than silicon carbide is used. Further, the present invention is similarly implemented when the conductivity types (n-type, p-type) are reversed.

The semiconductor device and the method of manufacturing a semiconductor device achieve an effect in that the impurity concentration and the depth of second-conductivity-type voltage withstanding regions may be easily adjusted, formation of the voltage withstanding structure having a high degree of completeness is facilitated, and a highly reliable semiconductor device may be provided.

As described above, the semiconductor device and the method of manufacturing a semiconductor device according to the invention are useful for power semiconductors that control high voltage and large current.

Although the invention has been described with respect to a specific embodiment for a complete and clear disclosure, the appended claims are not to be thus limited but are to be construed as embodying all modifications and alternative constructions that may occur to one skilled in the art which fairly fall within the basic teaching herein set forth.

What is claimed is:

1. A semiconductor device having an active region through which a main current flows and a termination region surrounding a periphery of the active region, the semiconductor device, comprising:
a semiconductor substrate containing a semiconductor having a bandgap wider than a bandgap of silicon, the semiconductor substrate having a first main surface and a second main surface opposite to each other, the semiconductor substrate including a first-conductivity-type epitaxial layer that forms the first main surface of the semiconductor substrate;
a first semiconductor region of a first conductivity type, provided in the semiconductor substrate;
a second semiconductor region of a second conductivity type, selectivity provided in the semiconductor substrate in the active region, between the first main surface of the semiconductor substrate and the first semiconductor region;
a device element structure formed in the semiconductor substrate in the active region, the device element structure having a pn junction between the second semiconductor region and the first semiconductor region;
a first electrode electrically connected to the second semiconductor region;
a second electrode provided on the second main surface of the semiconductor substrate; and
a plurality of second-conductivity-type voltage withstanding regions each selectively provided in the semiconductor substrate in the termination region, between the first main surface of the semiconductor substrate and the first semiconductor region, separate from the device element structure, the second-conductivity-type voltage withstanding regions concentrically surrounding the periphery of the active region to form concentric circles in a plan view of the semiconductor device, and being each provided separate from one another in a radial direction of the concentric circles, wherein
the first main surface of the semiconductor substrate is a flat surface spanning both the active region and the termination region,
the second semiconductor region and the second-conductivity-type voltage withstanding regions are diffused regions, in each of which an impurity of the second conductivity type is introduced in a respective region selectively provided in a first portion of the first-conductivity-type epitaxial layer, and
the first semiconductor region is a second portion of the first-conductivity-type epitaxial layer excluding the first portion of the first-conductivity-type epitaxial layer, the second portion including regions, between any two of the second-conductivity-type voltage withstanding regions that are adjacent to each other, from bottoms of the second-conductivity-type voltage withstanding regions to the first main surface of the semiconductor substrate.

2. The semiconductor device according to claim 1, wherein
each of the second-conductivity-type voltage withstanding regions includes a plurality of second-conductivity-type regions each of which is adjacent to one another in a depth direction orthogonal to the first main surface of the semiconductor substrate.

3. The semiconductor device according to claim 1, further comprising
a first-conductivity-type region selectively provided in the first semiconductor region in the termination region, in contact with the second-conductivity-type voltage withstanding regions, the first-conductivity-type region having an impurity concentration higher than an impurity concentration of the first semiconductor region.

4. The semiconductor device according to claim 2, wherein
in the plurality of second-conductivity-type regions included in a respective one of the second-conductivity-type voltage withstanding regions, misalignment of respective positions of the second-conductivity-type regions in a direction of a normal of the concentric circles is in a range from 0.05 μm to 0.3 μm.

5. The semiconductor device according to claim 2, wherein
among the plurality of second-conductivity-type regions included in a respective one of the second-conductivity-type voltage withstanding regions, a width in a direction of a normal of the concentric circles of at least one of the plurality of second-conductivity-type regions is different from a width of other ones of the second-conductivity-type regions.

6. The semiconductor device according to claim 3, wherein
among the plurality of second-conductivity-type regions included in a respective one of the second-conductivity-type voltage withstanding regions, a width in a direction of a normal of the concentric circles of at least one of the plurality of second-conductivity-type regions is different from a width of other ones of the second-conductivity-type regions.

7. The semiconductor device according to claim 2, wherein
among the plurality of second-conductivity-type regions included in a respective one of the second-conductivity-type voltage withstanding regions, an impurity concentration of at least one of the second-conductivity-type regions differs from an impurity concentration of other ones of the second-conductivity-type regions.

8. The semiconductor device according to claim 3, wherein
among the plurality of second-conductivity-type regions included in a respective one of the second-conductivity-type voltage withstanding regions, an impurity concentration of at least one of the second-conductivity-type regions differs from an impurity concentration of other ones of the second-conductivity-type regions.

9. The semiconductor device according to claim 2, wherein
a number of the plurality of second-conductivity-type regions included in a respective one of the second-conductivity-type voltage withstanding regions is at least three, and
of the at least three of the second-conductivity-type regions, an impurity concentration of one near a center of the second-conductivity-type voltage withstanding regions in the depth direction is lower than an impurity concentration of other ones of the at least three of the second-conductivity-type regions.

10. The semiconductor device according to claim 3, wherein
a number of the plurality of second-conductivity-type regions included in a respective one of the second-conductivity-type voltage withstanding regions is at least three, and
of the at least three of the second-conductivity-type regions, an impurity concentration of one near a center of the second-conductivity-type voltage withstanding regions in the depth direction is lower than an impurity concentration of other ones of the at least three of the second-conductivity-type regions.

11. The semiconductor device according to claim 2, wherein
the device element structure includes:
a plurality of third semiconductor regions of the first conductivity type, selectively provided in the semiconductor substrate, between the first main surface of the semiconductor substrate and the second semiconductor region;
a plurality of trenches penetrating through the third semiconductor regions and the second semiconductor region, and reaching the first semiconductor region;
a plurality of gate electrodes that are respectively provided in the trenches via a respective one of a plurality of gate insulating films;
a plurality of fourth semiconductor regions of the second conductivity type, selectively provided in the semiconductor substrate, between the first main surface of the semiconductor substrate and the second semiconductor region, at positions farther from the trenches than are the third semiconductor regions in the plan view, the fourth semiconductor regions having an impurity concentration higher than an impurity concentration of the second semiconductor region; and
a plurality of second-conductivity-type high-concentration regions, selectively provided in the first semiconductor region, and being each positioned closer to the second main surface of the semiconductor substrate than are bottoms of the trenches, the second-conductivity-type high-concentration regions having an impurity concentration higher than the impurity concentration of the second semiconductor region,
a number of the plurality of second-conductivity-type regions included in a respective one of the second-conductivity-type voltage withstanding regions is three,
of the three of the second-conductivity-type regions included in the respective one of the second-conductivity-type voltage withstanding regions:
a first second-conductivity-type region that is closest to the first main surface of the semiconductor substrate has an impurity concentration that is the same as an impurity concentration of the fourth semiconductor regions,
a second second-conductivity-type region that is farthest from the first main surface of the semiconductor substrate has an impurity concentration that is the same as the impurity concentration of the second-conductivity-type high-concentration regions, and
a remaining third second-conductivity-type region has an impurity concentration that is the same as the impurity concentration of the second semiconductor region.

12. The semiconductor device according to claim 3, wherein
the device element structure includes:
a plurality of third semiconductor regions of the first conductivity type, selectively provided in the semiconductor substrate, between the first main surface of the semiconductor substrate and the second semiconductor region;
a plurality of trenches penetrating through the third semiconductor regions and the second semiconductor region, and reaching the first semiconductor region;
a plurality of gate electrodes that are respectively provided in the trenches via a respective one of a plurality of gate insulating films;
a plurality of fourth semiconductor regions of the second conductivity type, selectively provided in the semiconductor substrate, between the first main surface of the semiconductor substrate and the second semiconductor region, at positions farther from the trenches than are the third semiconductor regions in the plan view, the fourth semiconductor regions having an impurity concentration higher than an impurity concentration of the second semiconductor region; and
a plurality of second-conductivity-type high-concentration regions, selectively provided in the first semiconductor region, and being each positioned closer to the second main surface of the semiconductor substrate than are bottoms of the trenches, the second-conductivity-type high-concentration regions having an impurity concentration higher than the impurity concentration of the second semiconductor region,
a number of the plurality of second-conductivity-type regions included in a respective one of the second-conductivity-type voltage withstanding regions is three,
of the three of the second-conductivity-type regions included in the respective one of the second-conductivity-type voltage withstanding regions:
a first second-conductivity-type region that is closest to the first main surface of the semiconductor substrate has an impurity concentration that is the same as an impurity concentration of the fourth semiconductor regions,
a second second-conductivity-type region that is farthest from the first main surface of the semiconductor substrate has an impurity concentration that is the same as the impurity concentration of the second-conductivity-type high-concentration regions, and
a remaining third second-conductivity-type region has an impurity concentration that is the same as the impurity concentration of the second semiconductor region.

13. The semiconductor device according to claim 1, wherein
the device element structure further includes:
a plurality of third semiconductor regions of the first conductivity type, selectively provided in the semiconductor substrate, between the first main surface of the semiconductor substrate and the second semiconductor region,
a plurality of trenches penetrating through the third semiconductor regions and the second semiconductor region, and reaching the first semiconductor region,
a plurality of gate electrodes that are respectively provided in the trenches via a respective one of a plurality of gate insulating films, and
a plurality of second-conductivity-type high-concentration regions selectively provided in the first semiconductor region, positioned closer to the second main surface of the semiconductor substrate than are bottoms of the trenches, the second-conductivity-type high-concentration regions having an impurity concentration higher than an impurity concentration of the second semiconductor region, and
the bottoms of the second-conductivity-type voltage withstanding regions are located deeper from the first main surface of the semiconductor substrate than are bottoms the second-conductivity-type high-concentration regions.

14. The semiconductor device according to claim 1, wherein
the device element structure further includes:
a plurality of third semiconductor regions of the first conductivity type, selectively provided between the first main surface of the semiconductor substrate and the second semiconductor region,
a plurality of trenches penetrating through the third semiconductor regions and the second semiconductor region, and reaching the first semiconductor region,
a plurality of gate electrodes that are respectively provided in the trenches via a respective one of a plurality of gate insulating films, and
a plurality of second-conductivity-type high-concentration regions selectively provided in the first semiconductor region, positioned closer to the second main surface of the semiconductor substrate than are bottoms of the trenches, the second-conductivity-type high-concentration regions having an impurity concentration higher than an impurity concentration of the second semiconductor region, and
the bottoms of the second-conductivity-type voltage withstanding regions are located shallower from the first main surface of the semiconductor substrate than are bottoms the second-conductivity-type high-concentration regions.

15. The semiconductor device according to claim 13, wherein
the second-conductivity-type high-concentration regions include:
a plurality of first high-concentration regions each facing a bottom of a respective one of the trenches in the depth direction, and
a plurality of second high-concentration regions each in contact with the second semiconductor region and separate from both the first high-concentration regions and the trenches.

16. The semiconductor device according to claim 14, wherein
the second-conductivity-type high-concentration regions include:
a plurality of first high-concentration regions each facing a bottom of a respective one of the trenches in the depth direction, and
a plurality of second high-concentration regions each in contact with the second semiconductor region and separate from both the first high-concentration regions and the trenches.

17. A method of manufacturing a semiconductor device having in a semiconductor substrate containing a semiconductor having a bandgap wider than a bandgap of silicon, the semiconductor device having an active region in which a predetermined device element structure having a pn junction between a first semiconductor region of a first conductivity type and a second semiconductor region of a second conductivity type is provided, and a termination region surrounding a periphery of the active region, the method comprising:
epitaxially growing a first-conductivity-type epitaxial layer forming a first main surface of the semiconductor substrate;
in a region to be the active region,
introducing an impurity of a second conductivity type in a surface region of the first-conductivity-type epitaxial layer, thereby forming a diffused region constituting at least the second semiconductor region, and
forming the device element structure that includes the pn junction between the second semiconductor region and the first semiconductor region, the first semiconductor region being a portion of the first-conductivity-type epitaxial layer, excluding the diffused region; and
in a region to be the termination region,
forming a plurality of second-conductivity-type voltage withstanding regions in surface regions of the first-conductivity-type epitaxial layer, separate from the device element structure, the second-conductivity-type voltage withstanding regions concentrically surrounding the periphery of the active region to form concentric circles, separate from one another in a radial direction of the concentric circles, thereby leaving the first-conductivity-type epitaxial layer between any two of the second-conductivity-type voltage withstanding regions that are adjacent to each other as the first semiconductor region, wherein
the epitaxially growing a first-conductivity-type epitaxial layer includes forming the first-conductivity-type epitaxial as a layered structure by depositing a plurality of layers of the first-conductivity-type epitaxial layer in multiple stages, and forming the first main surface of the semiconductor substrate to be flat spanning both the active region and the termination region, and
the forming a plurality of second-conductivity-type voltage withstanding regions includes forming second-conductivity-type regions in respective ones of the plurality of layers of the first-conductivity-type epitaxial layer, so that each of the second-conductivity-type voltage withstanding regions includes in the respective ones of the plurality of layers, a plurality of second-conductivity-type regions that are adjacent to one another in a depth direction orthogonal to the first main surface of the semiconductor substrate.

18. The method according to claim 17, wherein when a plurality of second-conductivity-type regions and the second semiconductor region are formed in a same one of the plurality of layers of the first-conductivity-type epitaxial layer, formation of the plurality of second-conductivity-type regions and formation of the second semiconductor region are concurrently performed.
